(19) United States
(12) Patent Application Publication
(10) Pub. No.: US 2019/0189934 A1
(43) Pub. Date: Jun. 20, 2019

(54) ORGANIC METAL COMPOUND AND ORGANIC LIGHT-EMITTING DEVICE

(71) Applicant: INDUSTRIAL TECHNOLOGY RESEARCH INSTITUTE, Hsinchu (TW)

(72) Inventors: Jia-Lun LIOU, Hengshan Township (TW); Jin-Sheng LIN, Taipei City (TW); Mei-Rurng TSENG, Hsinchu City (TW); Yi-Hsiang CHEN, Hsinchu City (TW)

(73) Assignee: INDUSTRIAL TECHNOLOGY RESEARCH INSTITUTE, Hsinchu (TW)

(21) Appl. No.: 15/856,537

(22) Filed: Dec. 28, 2017

(30) Foreign Application Priority Data
Dec. 18, 2017 (TW) 106144390

(51) Int. Cl. H01L 51/00; C07F 15/00; C09K 11/06

(52) U.S. Cl. CPC H01L 51/0085; C07F 15/0033; H01L 51/5016; H01L 51/0094; C09K 11/06

(57) ABSTRACT

Organic metal compounds, and organic light-emitting devices employing the same are provided. The organic metal compound has a chemical structure of Formula (I):

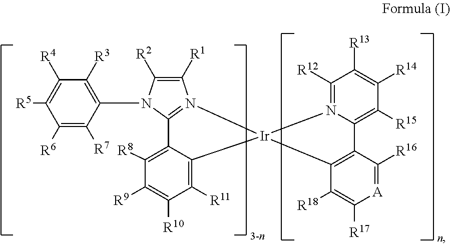

wherein at least one of R³, R⁴, R⁵, R⁶, R⁷, R⁸, R⁹, R¹⁰, and R¹¹ is —Si(R¹⁹)₃, or at least one of R¹², R¹³, R¹⁴, and R¹⁵ is —Si(R¹⁹)₃.

### CROSS REFERENCE TO RELATED APPLICATIONS

The application is based on, and claims priority from, Taiwan Application Serial Number 106144390, filed on Dec. 18, 2017, the disclosure of which is hereby incorporated by reference herein in its entirety.

### TECHNICAL FIELD

The disclosure relates to an organic metal compound and an organic light-emitting device employing the same.

### BACKGROUND

An organic electroluminescent device (a so-called “organic light-emitting diode (OLED)”) is a light-emitting diode (LED) that employs an organic electroluminescent layer as an active layer. Due to their advantages, including a low operating voltage, high brightness, light weight, wide viewing angle, and high contrast, organic electroluminescent devices are gradually being applied in flat panel displays. Unlike liquid-crystal displays, devices employing an organic light-emitting diode do not need a back-light source, thanks to spontaneous emission.

Generally, an organic light-emitting device is composed of a light-emission layer sandwiched between a pair of electrodes. When an electric field is applied to the electrodes, the cathode injects electrons into the light-emission layer and the anode injects holes into the light-emission layer. When the electrons recombine with the holes in the light-emission layer, excitons are formed. Recombination of the electron and hole results in light emission.

Depending on the spin states of the hole and electron, the exciton can have either a triplet or a singlet spin state. Luminescence from a singlet exciton results in fluorescence whereas luminescence from a triplet exciton results in phosphorescence. The emissive efficiency of phosphorescence is three times that of fluorescence. Therefore, it is crucial to develop a highly efficient phosphorescent material, in order to increase the emissive efficiency of an OLED.

### SUMMARY

According to embodiments of the disclosure, the disclosure provides an organic metal compound, which has a structure represented by Formula (I)

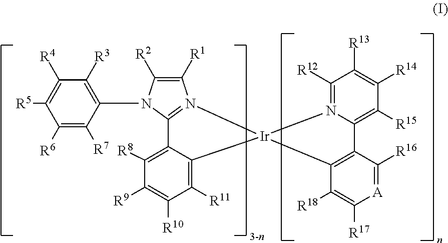

In particular, R¹ and R² are independently hydrogen, halogen, C₁₋₈ alkyl group, C₁₋₈ haloalkyl group, C₁₋₈ alkoxy group, C₅₋₁₀ cycloalkyl group, or C₆₋₁₂ aryl group; R³, R⁴, R⁵, R⁶, R⁷, R⁸, R⁹, R¹⁰, R¹, R¹², R¹³, R¹⁴ and R¹⁵ are independently hydrogen, halogen, C₁₋₈ alkyl group, C₁₋₈ haloalkyl group, C₁₋₈ alkoxy group, C₅₋₁₀ cycloalkyl group, C₆₋₁₂ aryl group or —Si(R¹⁹)₃, wherein R¹⁹ is independently C₁₋₈ alkyl group; R¹⁶, R¹⁷ and R¹⁸ are independently hydrogen, halogen, C₁₋₈ alkyl group, C₁₋₈ haloalkyl group, C₁₋₈ alkoxy group, C₅₋₁₀ cycloalkyl group, or C₆₋₁₂ aryl group; and, A is independently N or CR²⁰, wherein R²⁰ is independently hydrogen, halogen, or C₁₋₈ alkyl group. Moreover, n meets the following conditions (1), (2) and (3):

(1) n is 0, and at least one of R³, R⁴, R⁵, R⁶, R⁷, R⁸, R⁹, R¹⁰, and R¹ is —Si(R¹⁹)₃, wherein R¹⁹ is independently C₁₋₈ alkyl group; (2) n is 1 or 2, and at least one of R³, R⁴, R⁵, R⁶, R⁷, R⁸, R⁹, R¹, R, R¹², R¹³, R¹⁴ and R¹⁵ is —Si(R¹⁹)₃, wherein R¹⁹ is independently C₁₋₈ alkyl group; and, (3) n is 3, and at least one of R¹², R¹³, R¹⁴, and R¹⁵ is —Si(R¹⁹)₃, wherein R¹⁹ is independently C₁₋₈ alkyl group.

According to another embodiment of the disclosure, the disclosure provides an organic light-emitting device. The organic light-emitting device includes a pair of electrodes and an organic light-emitting element disposed between the electrodes, wherein the organic light-emitting element includes the aforementioned organic metal compound.

A detailed description is given in the following embodiments with reference to the accompanying drawings.

### BRIEF DESCRIPTION OF THE DRAWINGS

FIG. 1 shows a cross section of an organic light-emitting device disclosed by an embodiment of the disclosure.

### DETAILED DESCRIPTION

According to embodiments of the disclosure, the organic metal compound of the disclosure is a six-coordinate iridium compound having at least one of trialkylsilyl group. In particular, the coordinating ligand of the organic metal compound can be 1,2-diphenyl-1H-imidazole-based ligand and/or phenylpyridine-based (or bipyridine-based) ligand. Due to the specific chemical structure, the organic metal compound of the disclosure can have a suitable highest occupied molecular orbital (HOMO) and lowest unoccupied molecular orbital (LUMO) energy gap, thereby facilitating the electrons recombining with the holes to form excitons, and resulting in enhancing the luminescent efficiency of the organic light-emitting device employing the organic metal compound. In addition, due to the advantages of high electrochemical stability and thermal stability of the organic metal compound, the organic light-emitting device employing the organic metal compound can exhibit high operating lifespan and luminescent efficiency.

According to embodiments of the disclosure, the organic metal compound of the disclosure has a structure represented by Formula (I)

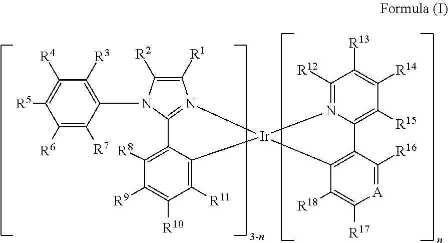

In particular, R¹ and R² can be independently hydrogen, halogen, C₁₋₈ alkyl group, C₁₋₈ haloalkyl group, C₁₋₈ alkoxy group, C₅₋₁₀ cycloalkyl group, or C₆₋₁₂ aryl group; R³, R⁴, R⁵, R⁶, R⁷, R⁸, R⁹, R¹⁰, R¹¹, R¹², R¹³, R¹⁴ and R¹⁵ can be independently hydrogen, halogen, C₁₋₈ alkyl group, C₁₋₈ haloalkyl group, C₁₋₈ alkoxy group, C₅₋₁₀ cycloalkyl group, C₆₋₁₂ aryl group, or —Si(R¹⁹)₃, wherein R¹⁹ can be independently C₁₋₈ alkyl group; R¹⁶, R¹⁷ and R¹⁸ can be independently hydrogen, halogen, C₁₋₈ alkyl group, C₁₋₈ haloalkyl group, C₁₋₈ alkoxy group, C₅₋₁₀ cycloalkyl group, or C₆₋₁₂ aryl group; and, A can be independently N, or CR²⁰, wherein R²⁰ can be independently hydrogen, halogen, or C₁₋₈ alkyl group. Moreover, n meets the following conditions (1), (2) and (3):

(1) n is 0, and at least one of R³, R⁴, R⁵, R⁶, R⁷, R⁸, R⁹, R¹⁰ and R¹¹ can be —Si(R¹⁹)₃, wherein R¹⁹ is independently C₁₋₈ alkyl group; (2) n is 1 or 2, and at least one of R³, R⁴, R⁵, R⁶, R⁷, R⁸, R⁹, R¹, R¹¹, R¹², R¹³, R¹⁴ and R¹⁵ can be —Si(R¹⁹)₃, wherein R¹⁹ is independently C₁₋₈ alkyl group; and, (3) n is 3, and at least one of R¹², R¹³, R¹⁴ and R¹⁵ can be —Si(R¹⁹)₃, wherein R¹⁹ is independently C₁₋₈ alkyl group.

According to embodiments of the disclosure, C₁₋₈ alkyl group can be linear or branched alkyl group. For example, C₁₋₈ alkyl group can be methyl group, ethyl group, propyl group, iso-propyl group, n-butyl group, tert-butyl group, sec-butyl group, iso-butyl group, pentyl group or hexyl group. According to embodiments of the disclosure, C₁₋₈ haloalkyl group can be an alkyl group which a part of or all hydrogen atoms bonded on the carbon atom are replaced with halogen atoms, and C₁₋₈ haloalkyl group can be linear or branched haloalkyl group. For example, fluoromethyl group can be monofluoromethyl group, difluoromethyl group or trifluoromethyl group. According to embodiments of the disclosure, C₁₋₈ alkoxy group can be linear or branched alkoxy group. For example, C₁₋₈ alkoxy group can be methoxy group, ethoxy group, propoxy group, isopropoxy group, butoxy group, sec-butoxy group, iso-butoxy group, tert-butoxy group, pentyloxy group, or hexyloxy group. According to embodiments of the disclosure, C₅₋₁₀ cycloalkyl group can be cyclopentyl group or cyclohexyl group. According to embodiments of the disclosure, C₆₋₁₂ aryl group can be phenyl group, biphenyl group or naphthyl group. According to embodiments of the disclosure, the group represented by —Si(R¹⁹)₃ can be trimethylsilyl group, triethylsilyl group, tripropylsilyl group, butyldimethylsilyl group, propyldimethylsilyl group or t-butyldimethylsilyl group.

According to embodiments of the disclosure, R¹ or R² can be independently hydrogen, fluorine, methyl group, ethyl group, propyl group, isopropyl group, butyl group, sec-butyl group, iso-butyl group, tert-butyl group, pentyl group, hexyl group, fluoromethyl, fluoroethyl, methoxy group, ethoxy group, propoxy group, isopropoxy group, butoxy group, sec-butoxy group, iso-butoxy group, tert-butoxy group, pentyloxy group, hexyloxy group, cyclopentyl group, cyclohexyl group, phenyl group, biphenyl group, or naphthyl group.

According to embodiments of the disclosure, R³, R⁴, R⁵, R⁶, R⁷, R⁸, R⁹, R¹⁰, R¹¹, R¹², R¹³, R¹⁴ and R¹⁵ are independently hydrogen, fluorine, methyl group, ethyl group, propyl group, isopropyl group, butyl group, sec-butyl group, iso-butyl group, tert-butyl group, pentyl group, hexyl group, fluoromethyl, fluoroethyl, methoxy group, ethoxy group, propoxy group, isopropoxy group, butoxy group, sec-butoxy group, iso-butoxy group, tert-butoxy group, pentyloxy group, hexyloxy group, cyclopentyl group, cyclohexyl group, phenyl group, biphenyl group, naphthyl group, or trialkylsilyl group.

According to embodiments of the disclosure, R¹⁶, R¹⁷, and R¹⁸ are independently hydrogen, fluorine, methyl group, ethyl group, propyl group, isopropyl group, butyl group, sec-butyl group, iso-butyl group, tert-butyl group, pentyl group, hexyl group, fluoromethyl, fluoroethyl, methoxy group, ethoxy group, propoxy group, isopropoxy group, butoxy group, sec-butoxy group, iso-butoxy group, tert-butoxy group, pentyloxy group, hexyloxy group, cyclopentyl group, cyclohexyl group, phenyl group, biphenyl group, or naphthyl group.

According to embodiments of the disclosure, R²⁰ can be independently hydrogen, fluorine, methyl group, ethyl group, propyl group, isopropyl group, butyl group, sec-butyl group, iso-butyl group, tert-butyl group, pentyl group, or hexyl group.

According to embodiments of the disclosure, since the organic metal compound of the disclosure having a structure represented by Formula (I) has at least one trialkylsilyl group, the organic metal compound of the disclosure can have a suitable highest occupied molecular orbital (HOMO) and lowest unoccupied molecular orbital (LUMO) energy gap, thereby facilitating the electrons recombining with the holes to form excitons, and exhibit superior electrochemical stability and thermal stability. As a result, the organic light-emitting device employing the organic metal compound can exhibit high operating lifespan and luminescent efficiency.

According to embodiments of the disclosure the organic metal compound having a structure represented by Formula (I) can be

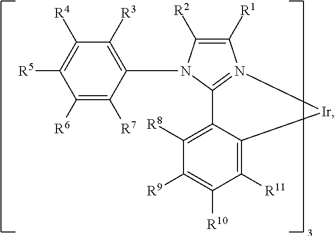

wherein R¹ and R² can be independently hydrogen, halogen, C₁₋₈ alkyl group, C₁₋₈ haloalkyl group, C₁₋₈ alkoxy group, C₅₋₁₀ cycloalkyl group, or C₆₋₁₂ aryl group; and, R³, R⁴, R⁵, R⁶, R⁷, R⁸, R⁹, R¹⁰ and R¹¹ can be independently hydrogen, halogen, C₁₋₈ alkyl group, C₁₋₈ haloalkyl group, C₁₋₈ alkoxy group, C₅₋₁₀ cycloalkyl group, C₆₋₁₂ aryl group, or —Si(R¹⁹)₃, wherein R¹⁹ can be independently C₁₋₈ alkyl group; and at least one of R³, R⁴, R⁵, R⁶, R⁷, R⁸, R⁹, R¹⁰ and R¹¹ can be —Si(R¹⁹)₃.

According to embodiments of the disclosure, the organic metal compound can be

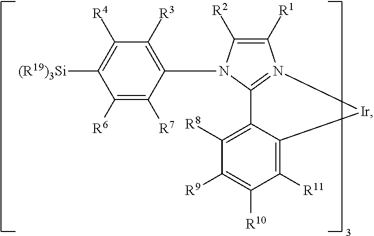

wherein R¹, R², R³, R⁴, R⁶, and R⁷ can be independently hydrogen, halogen, C₁₋₈ alkyl group, C₁₋₈ haloalkyl group, C₁₋₈ alkoxy group, C₅₋₁₀ cycloalkyl group, or C₆₋₁₂ aryl group; R⁸, R⁹, R¹⁰, and R¹¹ can be independently hydrogen, halogen, C₁₋₈ alkyl group, C₁₋₈ haloalkyl group, C₁₋₈ alkoxy group, C₅₋₁₀ cycloalkyl group, C₆₋₁₂ aryl group, or —Si(R¹⁹)₃; and, R¹⁹ can be independently C₁₋₈ alkyl group.

In addition, the organic metal compound can be

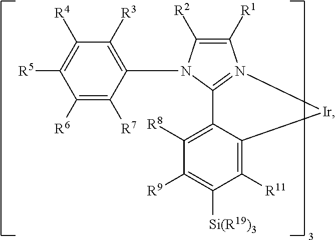

wherein R¹, R², R⁸, R⁹ and R¹¹ can be independently hydrogen, halogen, C₁₋₈ alkyl group, C₁₋₈ haloalkyl group, C₁₋₈ alkoxy group, C₅₋₁₀ cycloalkyl group, or C₆₋₁₂ aryl group; R³, R⁴, R⁵, R⁶ and R⁷ can be independently hydrogen, halogen, C₁₋₈ alkyl group, C₁₋₈ haloalkyl group, C₁₋₈ alkoxy group, C₅₋₁₀ cycloalkyl group, C₆₋₁₂ aryl group, or —Si(R¹⁹)₃; and, R¹⁹ can be independently C₁₋₈ alkyl group.

According to embodiments of the disclosure, the organic metal compound can be

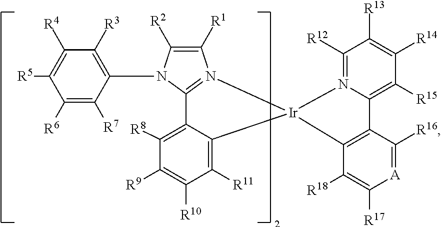

wherein R¹ and R² can be independently hydrogen, halogen, C₁₋₈ alkyl group, C₁₋₈ haloalkyl group, C₁₋₈ alkoxy group, C₅₋₁₀ cycloalkyl group, or C₆₋₁₂ aryl group; R³, R⁴, R⁵, R⁶, R⁷, R⁸, R⁹, R¹⁰, R¹¹, R¹², R¹³, R¹⁴ and R¹⁵ can be independently hydrogen, halogen, C₁₋₈ alkyl group, C₁₋₈ haloalkyl group, C₁₋₈ alkoxy group, C₅₋₁₀ cycloalkyl group, C₆₋₁₂ aryl group, or —Si(R¹⁹)₃, wherein R¹⁹ can be independently C₁₋₈ alkyl group; R¹⁶, R¹⁷, and R¹⁸ can be independently hydrogen, halogen, C₁₋₈ alkyl group, C₁₋₈ haloalkyl group, C₁₋₈ alkoxy group, C₅₋₁₀ cycloalkyl group, or C₆₋₁₂ aryl group; and, A is N, or CR²⁰, wherein R²⁰ is hydrogen, halogen, or C₁₋₈ alkyl group; and at least one of R³, R⁴, R⁵, R⁶, R⁷, R⁸, R⁹, R¹⁰, R¹¹, R¹², R¹³, R¹⁴ and R¹⁵ is —Si(R¹⁹)₃.

According to embodiments of the disclosure, the organic metal compound can be

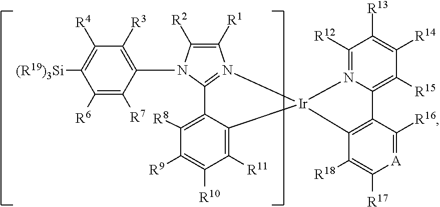

wherein R¹, R², R³, R⁴, R⁶, R⁷, R¹⁶, R¹⁷ and R¹⁸ can be independently hydrogen, halogen, C₁₋₈ alkyl group, C₁₋₈ haloalkyl group, C₁₋₈ alkoxy group, C₅₋₁₀ cycloalkyl group, or C₆₋₁₂ aryl group; R⁸, R⁹, R¹⁰, R¹¹, R¹², R, R¹⁴ and R¹⁵ can be independently hydrogen, halogen, C₁₋₈ alkyl group, C₁₋₈ haloalkyl group, C₁₋₈ alkoxy group, C₅₋₁₀ cycloalkyl group, C₆₋₁₂ aryl group, or —Si(R¹⁹)₃; R¹⁹ can be independently C₁₋₈ alkyl group; and, A is N, or CR²⁰, wherein R²⁰ is hydrogen, halogen, or C₁₋₈ alkyl group.

In addition, According to embodiments of the disclosure, the organic metal compound can be

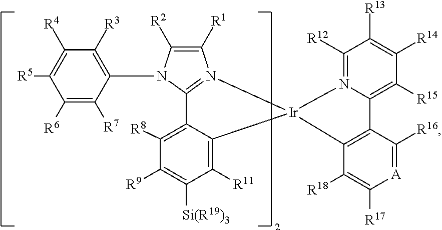

wherein R¹, R², R⁸, R⁹, R¹¹, R¹⁶, R¹⁷ and R¹⁸ can be independently hydrogen, halogen, C₁₋₈ alkyl group, C₁₋₈ haloalkyl group, C₁₋₈ alkoxy group, C₅₋₁₀ cycloalkyl group, or C₆₋₁₂ aryl group; R³, R⁴, R⁵, R⁶, R⁷, R¹², R¹³, R¹⁴ and R¹⁵ can be independently hydrogen, halogen, C₁₋₈ alkyl group, C₁₋₈ haloalkyl group, C₁₋₈ alkoxy group, C₅₋₁₀ cycloalkyl group, C₆₋₁₂ aryl group, or —Si(R¹⁹)₃; R¹⁹ can be independently C₁₋₈ alkyl group; and, A is N, or CR²⁰, wherein R²⁰ is hydrogen, halogen, or C₁₋₈ alkyl group.

Furthermore, according to embodiments of the disclosure, the organic metal compound can be

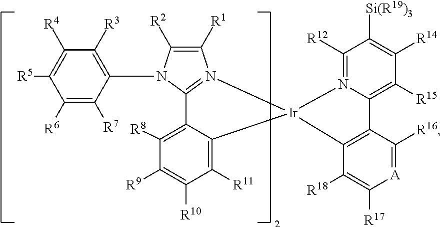

wherein R¹, R², R¹², R¹⁴, R¹⁵, R¹⁶, R¹⁷ and R¹⁸ can be independently hydrogen, halogen, C₁₋₈ alkyl group, C₁₋₈ haloalkyl group, C₁₋₈ alkoxy group, C₅₋₁₀ cycloalkyl group, or C₆₋₁₂ aryl group; R³, R⁴, R⁵, R⁶, R⁷, R⁸, R⁹, R¹⁰ and R¹¹ can be independently hydrogen, halogen, C₁₋₈ alkyl group, C₁₋₈ haloalkyl group, C₁₋₈ alkoxy group, C₅₋₁₀ cycloalkyl group, C₆₋₁₂ aryl group, or —Si(R¹⁹)₃; R¹⁹ can be independently C₁₋₈ alkyl group; and, A is N, or CR²⁰, wherein R²⁰ is hydrogen, halogen, or C₁₋₈ alkyl group.

According to embodiments of the disclosure, the organic metal compound can be

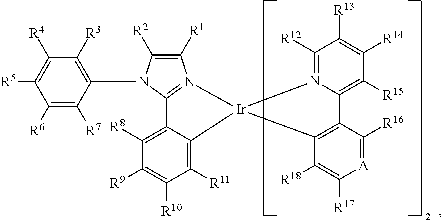

wherein R¹, R², R¹⁶, R¹⁷ and R¹⁸ can be independently hydrogen, halogen, C₁₋₈ alkyl group, C₁₋₈ haloalkyl group, C₁₋₈ alkoxy group, C₅₋₁₀ cycloalkyl group, or C₆₋₁₂ aryl group; R³, R⁴, R⁵, R⁶, R⁷, R⁸, R⁹, R¹⁰, R¹¹, R¹², R¹³, R¹⁴ and R¹⁵ can be independently hydrogen, halogen, C₁₋₈ alkyl group, C₁₋₈ haloalkyl group, C₁₋₈ alkoxy group, C₅₋₁₀ cycloalkyl group, C₆₋₁₂ aryl group, or —Si(R¹⁹)₃, wherein R¹⁹ can be independently C₁₋₈ alkyl group; and, A is independently N, or CR²⁰, wherein R²⁰ can be independently hydrogen, halogen, or C₁₋₈ alkyl group; and at least one of R³, R⁴, R⁵, R⁶, R⁷, R⁸, R⁹, R¹⁰, R¹¹, R¹², R¹³, R¹⁴ and R¹⁵ is —Si(R¹⁹)₃.

According to embodiments of the disclosure, the organic metal compound can be

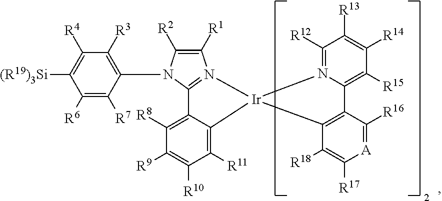

wherein R¹, R², R³, R⁴, R⁶, R⁷, R¹⁶, R¹⁷ and R¹⁸ can be independently hydrogen, halogen, C₁₋₈ alkyl group, C₁₋₈ haloalkyl group, C₁₋₈ alkoxy group, C₅₋₁₀ cycloalkyl group, or C₆₋₁₂ aryl group; R⁸, R⁹, R¹⁰, R¹¹, R¹², R, R¹⁴ and R¹⁵ can be independently hydrogen, halogen, C₁₋₈ alkyl group, C₁₋₈ haloalkyl group, C₁₋₈ alkoxy group, C₅₋₁₀ cycloalkyl group, C₆₋₁₂ aryl group, or —Si(R¹⁹)₃; R¹⁹ can be independently C₁₋₈ alkyl group; and, A is independently N, or CR²⁰, wherein R²⁰ can be independently hydrogen, halogen, or C₁₋₈ alkyl group.

In addition, According to embodiments of the disclosure, the organic metal compound can be

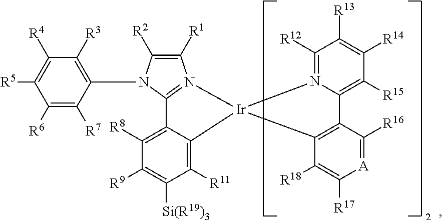

wherein R¹, R², R⁸, R⁹, R¹¹, R¹⁶, R⁷ and R¹⁸ can be independently hydrogen, halogen, C₁₋₈ alkyl group, C₁₋₈ haloalkyl group, C₁₋₈ alkoxy group, C₅₋₁₀ cycloalkyl group, or C₆₋₁₂ aryl group; R³, R⁴, R⁵, R⁶, R⁷, R¹², R¹³, R¹⁴ and R¹⁵ can be independently hydrogen, halogen, C₁₋₈ alkyl group, C₁₋₈ haloalkyl group, C₁₋₈ alkoxy group, C₅₋₁₀ cycloalkyl group, C₆₋₁₂ aryl group, or —Si(R¹⁹)₃; R¹⁹ can be independently C₁₋₈ alkyl group; and, A is independently N, or CR²⁰, wherein R²⁰ can be independently hydrogen, halogen, or C₁₋₈ alkyl group.

Furthermore, According to embodiments of the disclosure, the organic metal compound can be

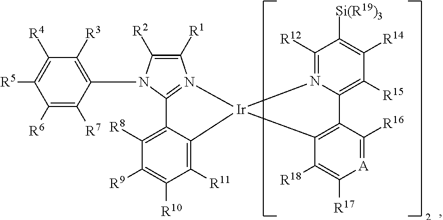

wherein R¹, R², R¹², R¹⁴, R¹⁵, R¹⁶, R¹⁷ and R¹⁸ can be independently hydrogen, halogen, C₁₋₈ alkyl group, C₁₋₈ haloalkyl group, C₁₋₈ alkoxy group, C₅₋₁₀ cycloalkyl group, or C₆₋₁₂ aryl group; R³, R⁴, R⁵, R⁶, R⁷, R⁸, R⁹, R¹⁰ and R¹¹ can be independently hydrogen, halogen, C₁₋₈ alkyl group, C₁₋₈ haloalkyl group, C₁₋₈ alkoxy group, C₅₋₁₀ cycloalkyl group, C₆₋₁₂ aryl group, or —Si(R¹⁹)₃; R¹⁹ can be independently C₁₋₈ alkyl group; and, A is independently N, or CR²⁰, wherein R²⁰ can be independently hydrogen, halogen, or C₁₋₈ alkyl group.

According to embodiments of the disclosure, the organic metal compound can be

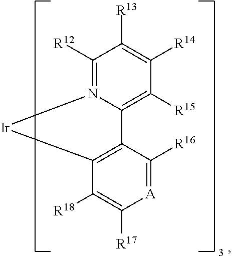

wherein R¹⁶, R¹⁷ and R¹⁸ can be independently hydrogen, halogen, C₁₋₈ alkyl group, C₁₋₈ haloalkyl group, C₁₋₈ alkoxy group, C₅₋₁₀ cycloalkyl group, or C₆₋₁₂ aryl group; R¹², R¹³, R¹⁴ and R¹⁵ can be independently hydrogen, halogen, C₁₋₈ alkyl group, C₁₋₈ haloalkyl group, C₁₋₈ alkoxy group, C₅₋₁₀ cycloalkyl group, C₆₋₁₂ aryl group, or —Si(R¹⁹)₃, and at least one of R¹², R¹³, R¹⁴ and R¹⁵ is —Si(R¹⁹)₃; R¹⁹ can be independently C₁₋₈ alkyl group; and, A is independently N, or CR²⁰, wherein R²⁰ can be independently hydrogen, halogen, or C₁₋₈ alkyl group.

According to embodiments of the disclosure, the organic metal compound can be

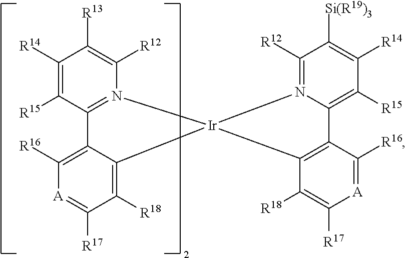

wherein R¹², R¹³, R¹⁴, R¹⁵, R¹⁶, R¹⁷ and R¹⁸ can be independently hydrogen, halogen, C₁₋₈ alkyl group, C₁₋₈ haloalkyl group, C₁₋₈ alkoxy group, C₅₋₁₀ cycloalkyl group, or C₆₋₁₂ aryl group; R¹⁹ can be independently C₁₋₈ alkyl group; and, A is independently N, or CR²⁰, wherein R²⁰ can be independently hydrogen, halogen, or C₁₋₈ alkyl group.

According to embodiments of the disclosure, the organic metal compound can be

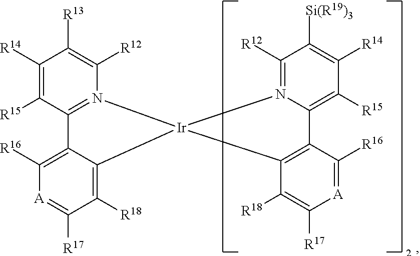

wherein R¹², R¹³, R¹⁴, R¹⁵, R¹⁶, R¹⁷ and R¹⁸ can be independently hydrogen, halogen, C₁₋₈ alkyl group, C₁₋₈ haloalkyl group, C₁₋₈ alkoxy group, C₅₋₁₀ cycloalkyl group, or C₆₋₁₂ aryl group; R¹⁹ can be independently C₁₋₈ alkyl group; and, A is independently N, or CR²⁰, wherein R²⁰ can be independently hydrogen, halogen, or C₁₋₈ alkyl group.

Below, exemplary embodiments will be described in detail so as to be easily realized by a person having ordinary knowledge in the art. The inventive concept may be embodied in various forms without being limited to the exemplary embodiments set forth herein. Descriptions of well-known parts are omitted for clarity.

The organic metal compounds having the structure represented by Formula (I) of the disclosure include the following compounds shown in Table 1 and the structures thereof are shown in Table 1.

TABLE 1

| | structure of organic metal compound |
|---|---|
| Example 1 | 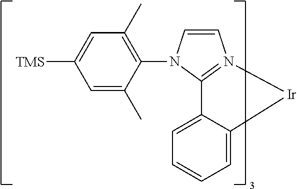 Organic metal compound (I) |
| Example 2 | 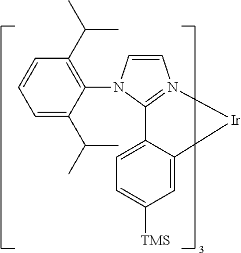 Organic metal compound (II) |
| Example 3 | 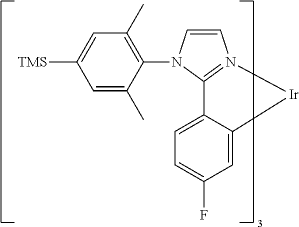 Organic metal compound (III) |
| Example 4 | 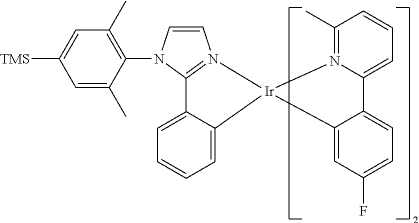 Organic metal compound (IV) |
| Example 5 | 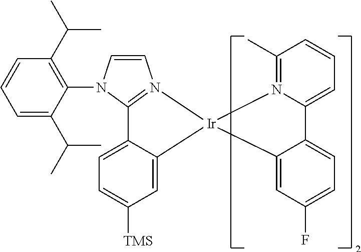 Organic metal compound (V) |
| Example 6 | 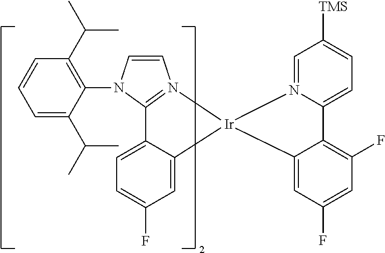 Organic metal compound (VI) |
| Example 7 | 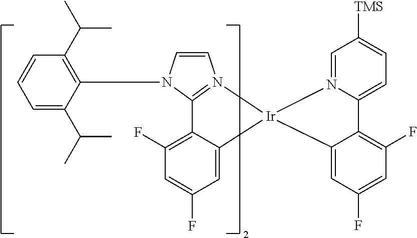 Organic metal compound (VII) |
| Example 8 | 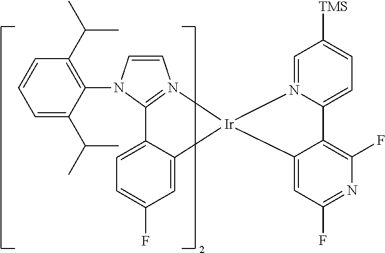 Organic metal compound (VIII) |
| Example 9 | 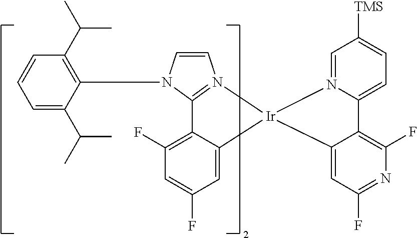 Organic metal compound (IX) |
| Example 10 | 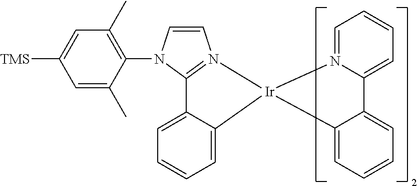 Organic metal compound (X) |
| Example 11 | 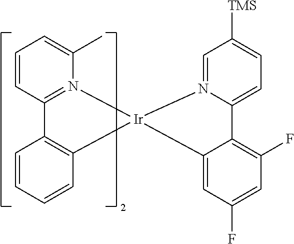 Organic metal compound (XI) |
| Example 12 | 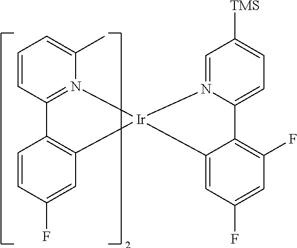 Organic metal compound (XII) |

(TMS: (CH₃)₃Si—)

In order to clearly illustrate the method for preparing the organic metal compound of the disclosure, the preparation of compounds disclosed in Examples 2 and 7 are described in detail as below.

Preparation of Organic Metal Compound (II)

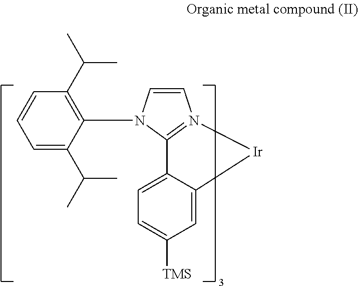

2,6-diisopropylaniline) (2.84 g, 16 mmole) and 60 mL of anhydrous tetrahydrofuran (THF) were added into a reaction bottle in nitrogen atmosphere. Next, the reaction bottle was cooled to 0° C., and n-butyl lithium (n-BuLi) (11 mL, 17.6 mmol, 1.6 M) was added dropwise into the reaction bottle at 0° C. After addition of n-butyl lithium, the mixture was stirred for 30 min at room temperature. Next, bromoacetaldehyde diethyl acetal (3.5 g, 17.6 mmole) was added into the reaction bottle at room temperature. After stirring at room temperature for 18 hr, 50 mL of aqueous sodium bicarbonate solution (the weight ratio between NaHCO₃ and H₂O is 1:1). Next, the result was extracted three times using ethyl acetate (EA) and water as the extraction solvent. Next, an organic phase was separated, dried, filtrated and concentrated by rotary evaporator, and then purified by column chromatography with ethyl acetate/n-hexane (1:30) as the extraction solvent, obtaining Compound (1) with a yield of 89%. The synthesis pathway of the above reaction was as follows:

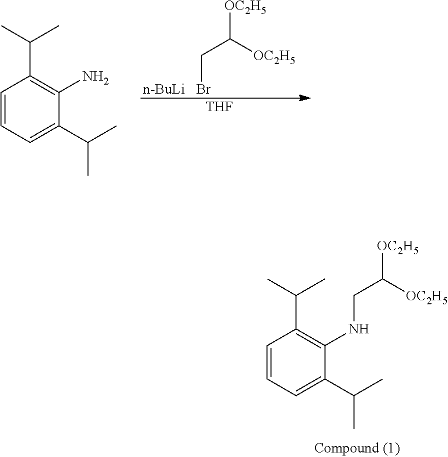

Next, a reaction bottle was provided, and Compound (1) (2.93 g, 10 mmole) and dichloromethane (CH₂Cl₂) (20 mL) were added into the reaction bottle. Next, the reaction bottle was cooled to 0° C., and 4-bromobenzoyl chloride (10.9 g, 50 mmole) was added into the reaction bottle at 0° C. After stirring, triethylamine (Et₃N) (2.78 mL, 20 mmole) was added slowly into the reaction bottle. After stirring at room temperature for 8 hr, the result was concentrated by rotary evaporator to remove the solvent, obtaining a yellow solid. Next, the obtained solid, acetone (18 mL), and H₂O (2 mL) was added into another reaction bottle. Next, p-toluenesulfonic acid (p-TsOH) (4 g, 21 mmole) was added into the reaction bottle, and then the reaction bottle was heated to and then the reaction bottle was heated to reflux. After reacting for 2 hr, the reaction bottle was cooled to room temperature, and the result was concentrated by rotary evaporator to remove the solvent. Next, an aqueous sodium bicarbonate solution (the weight ratio between NaHCO₃ and H₂O is 1:1) was added into the reaction bottle, and the result was extracted three times using ethyl acetate (EA) and water as the extraction solvent. Next, an organic phase was separated, dried, filtrated and concentrated by rotary evaporator, obtaining Compound (2). Next, Compound (2) and acetic anhydride (15 mL) were added into a reaction bottle. After cooling to 0° C., aqueous tetrafluoroboric acid (HBF₄) (1.5 mL, 12 mmole) solution (50%) was added dropwise into the reaction bottle. After stirring for 8 hr, ethyl ether (100 mL) was added into the reaction bottle. After stirring for 30 min, an off-white solid was precipitated. Next, the result was filtrated and then the filter cake was washed by ethyl ether. After drying by a vacuum, Compound (3) was obtained. The synthesis pathway of the above reaction was as follows:

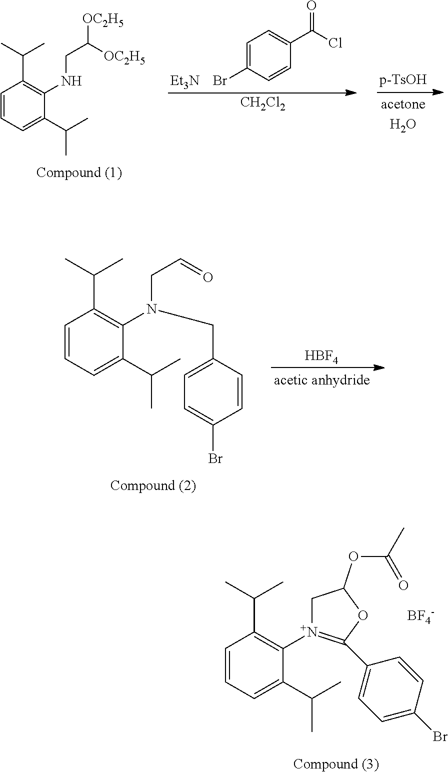

Next, oxazolium salt (5.31 g, 10 mmole) and acetonitrile (CH₃CN) (30 mL) were added into a reaction bottle. Next, ammonium acetate (NH₄OAc) (1.31 g, 17 mmole) was added into the reaction bottle, and then the result was stirred at room temperature for 24 hr. Next, aqueous tetrafluoroboric acid (HBF₄) (2.11 mL, 17 mmole) solution (50%) was added dropwise into the reaction bottle, and then the result was heated at 80° C. for 8 hr. After cooling to room temperature, the result was concentrated by rotary evaporator to remove the solvent, and then the aqueous sodium bicarbonate solution (the weight ratio between NaHCO₃ and H₂O is 1:1) was added into the reaction bottle at 0° C. Next, the result was extracted three times using ethyl acetate (EA) and water as the extraction solvent. Next, an organic phase was separated, dried, filtrated and concentrated by rotary evaporator, and then purified by column chromatography with ethyl acetate/n-hexane (1:15) as the extraction solvent, obtaining Compound (4). The synthesis pathway of the above reaction was as follows:

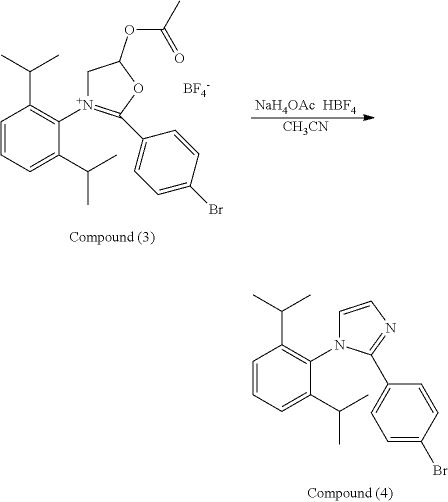

Compound (4) (3.85 g, 10 mmole) and 100 mL of anhydrous tetrahydrofuran (THF) were added into a reaction bottle in nitrogen atmosphere. Next, n-butyl lithium (n-BuLi) (11 mL, 17.6 mmol, 1.6 M) was added dropwise into the reaction bottle at −78° C. After addition of n-butyl lithium, the mixture was stirred for 1 hr at −78° C. Next, trimethylsilyl chloride, TMSCl (1.5 mL, 12 mmole) was added into the reaction bottle. Next, after heating to room temperature, the mixture was stirred for 3 hr. Next, water was added into the reaction bottle. Next, the result was extracted three times using ethyl acetate (EA) and water as the extraction solvent. Next, an organic phase was separated, dried, filtrated and concentrated by rotary evaporator, and then purified by column chromatography with ethyl acetate/n-hexane (1:10) as the extraction solvent, obtaining Compound (5). The synthesis pathway of the above reaction was as follows:

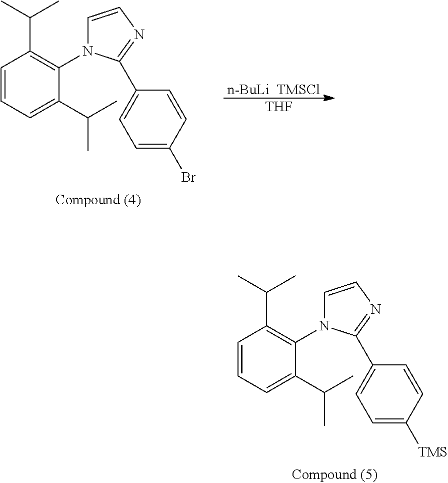

Next, a reaction bottle was provided, and Compound (5) (2.48 g, 6.6 mmole), iridium trichloride (IrCl₃) (0.89 g, 3 mmole), 2-methoxyethanol (24 mL) and water (8 mL) were added into the reaction bottle. Next, after removing moisture and purging nitrogen gas several times, the reaction bottle was heated to reflux (120° C.). After reacting for 24 hr, the reaction bottle was heated to room temperature, and then water was added into the reaction bottle. After filtrating, the filter cake was washed by water and n-hexane. After drying by a vacuum, Compound (6) was obtained. The synthesis pathway of the above reaction was as follows:

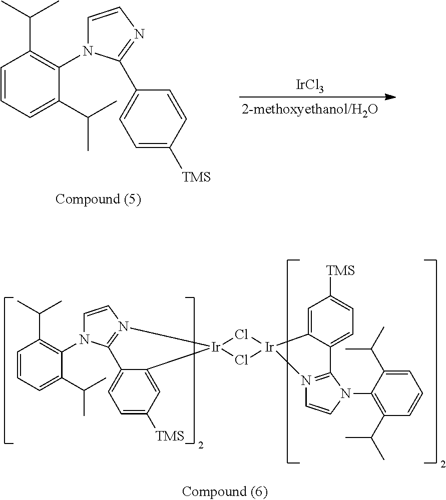

Next, a reaction bottle was provided, and Compound (6) (2 g, 1 mmole), acetylacetone (0.4 g, 4 mmole), triethylamine triethylamine (Et₃N) (0.5 ml, 4 mmole) and 2-methoxyethanol (10 mL) were added into the reaction bottle. Next, after removing moisture and purging nitrogen gas several times, the reaction bottle was heated to 120° C. in nitrogen atmosphere. After reacting for 3 hr, the reaction bottle was heated to room temperature, and then water was added into the reaction bottle. After filtrating, the filter cake was washed by water and n-hexane and then dissolved in dichloromethane (CH₂Cl₂). Next, the result was extracted three times using dichloromethane (CH₂Cl₂) and water as the extraction solvent. Next, an organic phase was separated, dried, filtrated and concentrated by rotary evaporator, and then purified by column chromatography with ethyl acetate/n-hexane (1:10) as the extraction solvent, obtaining Compound (7). The synthesis pathway of the above reaction was as follows:

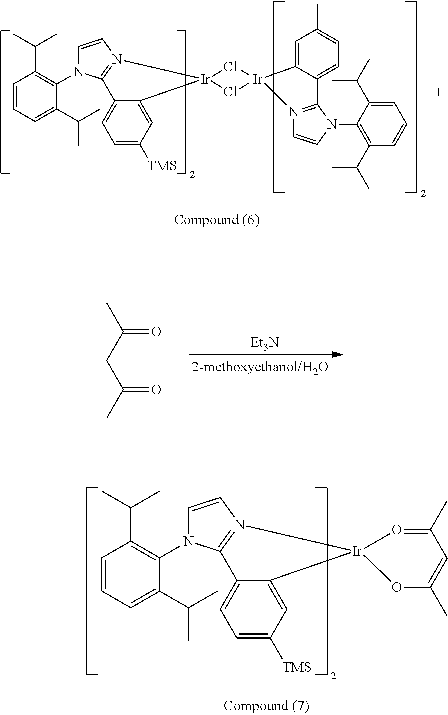

Next, Compound (7) (1 g, 1 mmole), Compound (5) (0.75 g, 2 mmole) and ethylene glycol (20 mL) were added into a reaction bottle. Next, the reaction bottle was heated to 160° C. in nitrogen atmosphere. After stirring for 48 hr, the reaction bottle was cooled to room temperature, and water (30 mL) was added into the reaction bottle. After stirring, the precipitated solid was collected, and then washed by water. After drying, the solid was purified by column chromatography with ethyl acetate/n-hexane (1:40) as the extraction solvent, obtaining Organic metal compound (II). The synthesis pathway of the above reaction was as follows:

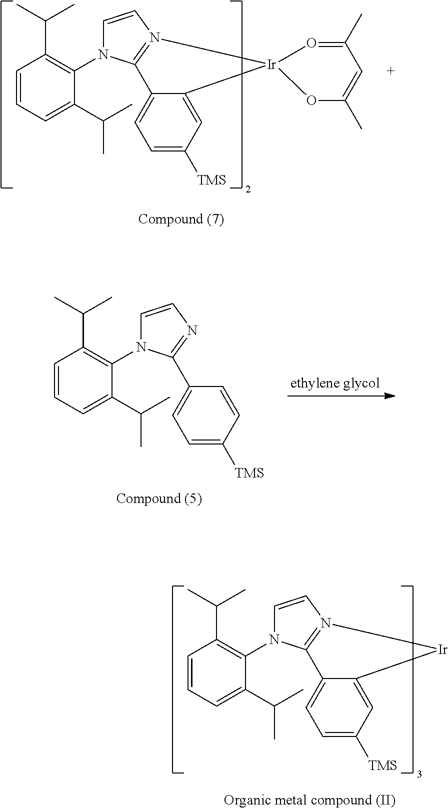

Preparation of Organic Metal Compound (VII)

A reaction bottle was provided, and Compound (8) (2.2 g, 6.6 mmole), iridium trichloride (IrCl₃) (0.89 g, 3 mmole), 2-methoxyethanol (24 mL) and water (8 mL) were added into the reaction bottle. Next, after removing moisture and purging nitrogen gas several times, the reaction bottle was heated to reflux (120° C.) in nitrogen atmosphere. After reacting for 24 hr, the reaction bottle was heated to room temperature, and then water was added into the reaction bottle. After filtrating, the filter cake was washed by water and n-hexane. After drying by a vacuum, Compound (9) was obtained. The synthesis pathway of the above reaction was as follows:

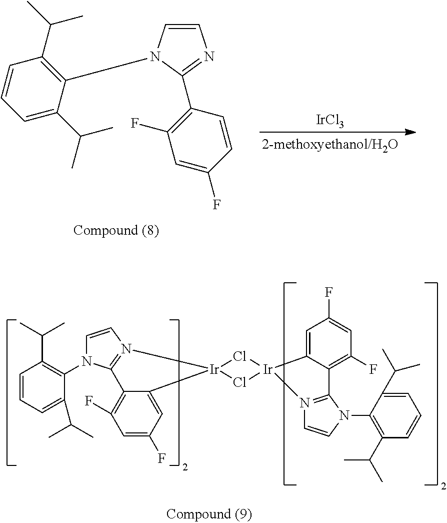

Next, a reaction bottle was provided, and Compound (9) (2 g, 1 mmole) and dichloromethane (5 mL) were added into the reaction bottle. Next, silver trifluoroacetate (AgOCOCF₃) (0.56 g, 2.2 mmole) dissolved in methanol (5 mL) was added into the reaction bottle. Next, after reacting at room temperature for 12 hr, the result was filtrated by celite and filter paper, and the filtrate was collected. Next, the filtrate was washed by dichloromethane. After concentrating by rotary evaporator, Compound (10) was obtained. The synthesis pathway of the above reaction was as follows:

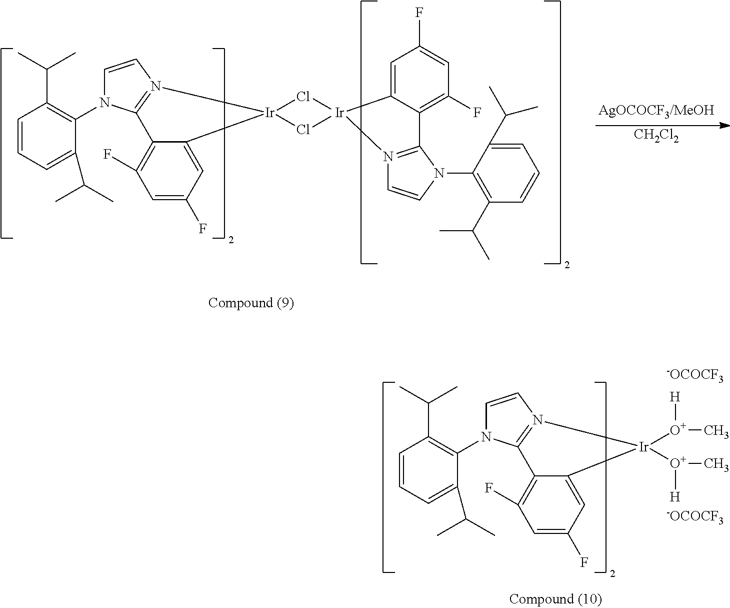

Next, 2-bromo-5-trimethylsilylpyridine (0.7 g, 3 mmole), 2,4-difluoro benzene boronic acid (0.52 g, 3.3 mmole), K₂CO₃ (0.4 g, 3 mmole), dimethoxyethane (DME) (20 mL) and water (10 mL) were added into a reaction bottle. Next, a catalytic amount of tetrakis(triphenyl phosphine) palladium (Pd(PPh₃)₄) was added into the reaction bottle. After removing moisture and purging nitrogen gas several times, the reaction bottle was heated to reflux. After reacting for 8 hr, the reaction bottle was cooled to room temperature, and then the aqueous sodium bicarbonate solution (the weight ratio between NaHCO₃ and H₂O is 1:1) was added into the reaction bottle to neutralize the mixture. Next, the result was extracted three times using ethyl acetate (EA) and water as the extraction solvent. Next, an organic phase was separated, dried, filtrated and concentrated by rotary evaporator, and then purified by column chromatography with ethyl acetate/n-hexane (1:40) as the extraction solvent, obtaining Compound (11). The synthesis pathway of the above reaction was as follows.

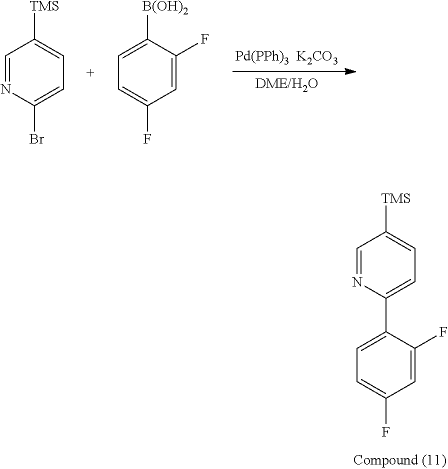 [SMILES: C[Si](C)(C)c1ccc(Br)nc1 ; OB(O)c1ccc(F)cc1F ; C[Si](C)(C)c1ccc(-c2ccc(F)cc2F)nc1]

Next, Compound (10) (1 g, 1 mmole), Compound (11)(0.4 g, 1.5 mmole), methanol (MeOH) (1 mL) and ethanol (EtOH) (1 mL) were added into a reaction bottle. Next, after reacting at 90° C. for 12 hr, the reaction bottle was cooled to room temperature. Next, the result was extracted three times using dichloromethane (CH₂Cl₂) and water as the extraction solvent. Next, an organic phase was separated, dried, filtrated and concentrated by rotary evaporator, and then purified by column chromatography with ethyl acetate/n-hexane (1:4) as the extraction solvent, obtaining Organic metal compound (VII). The synthesis pathway of the above reaction was as follows:

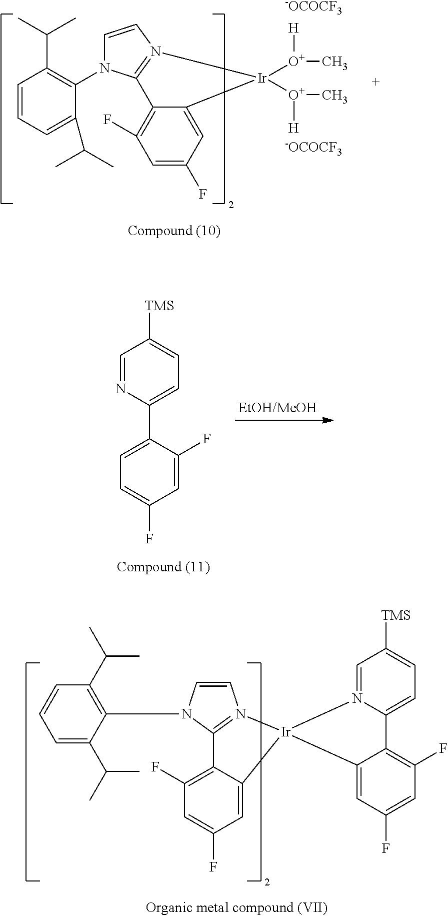

Preparation of Organic Metal Compound (V)

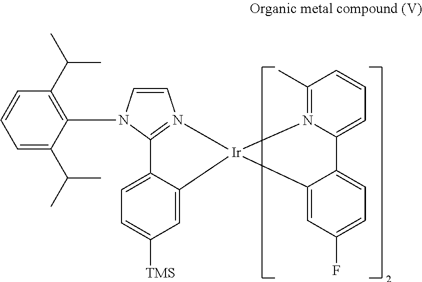

2-bromo-6-methylpyridine (0.52 g, 3 mmole), 4-fluorophenylboronic acid (0.5 g, 3.6 mmole), K₂CO₃ (0.4 g, 3 mmole), dimethoxyethane (20 mL) and water (10 mL) were added into a reaction bottle. Next, a catalytic amount of tetrakis(triphenyl phosphine) palladium (Pd(PPh₃)₄) was added into the reaction bottle. After removing moisture and purging nitrogen gas several times, the reaction bottle was heated to reflux. After reacting for 8 hr, the reaction bottle was cooled to room temperature, the aqueous sodium bicarbonate solution (the weight ratio between NaHCO₃ and H₂O is 1:1) was added into the reaction bottle to neutralize the mixture. Next, the result was extracted three times using ethyl acetate (EA) and water as the extraction solvent. Next, an organic phase was separated, dried, filtrated and concentrated by rotary evaporator, and then purified by column chromatography with ethyl acetate/n-hexane (1:40) as the extraction solvent, obtaining Compound (12). The synthesis pathway of the above reaction was as follows:

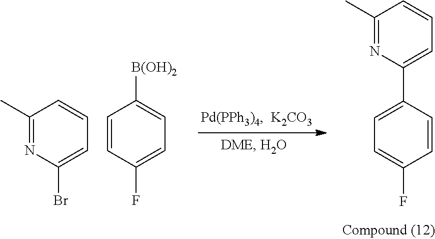

Next, a reaction bottle was provided, and Compound (12) (1.23 g, 6.6 mmole), iridium trichloride (IrCl₃) (0.89 g, 3 mmole), 2-methoxyethanol (24 mL), and water (8 mL) were added into the reaction bottle. Next, after removing moisture and purging nitrogen gas several times, the reaction bottle was heated to reflux (120° C.). After reacting for 18 hr, the reaction bottle was cooled to room temperature. After adding water into the reaction bottle, the result was filtrated, and the filter cake was washed with water and n-hexane. After drying by a vacuum, Compound (13) was obtained. The synthesis pathway of the above reaction was as follows:

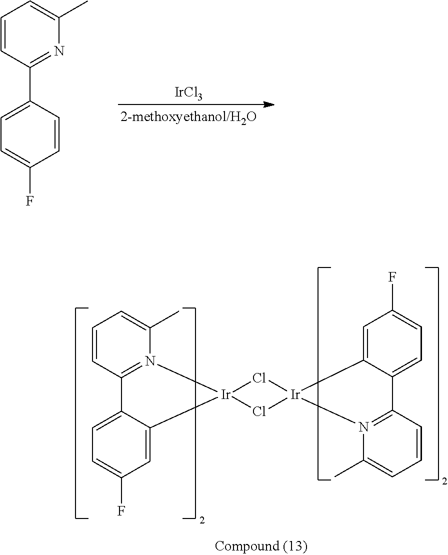

Compound (13) (1.2 g, 1 mmole), Compound (5) (0.94 g, 2.5 mmole), silver trifluoromethanesulfonate (AgOTf) (0.56 g, 2.2 mmole), methanol (MeOH) (5 mL) and ethanol (EtOH) (5 mL) were added into a reaction bottle. Next, the mixture was stirred at 90° C. for 12 hr. After cooling to room temperature, the result was extracted three times using dichloromethane (CH₂Cl₂) and water as the extraction solvent. Next, an organic phase was separated, dried, filtrated and concentrated by rotary evaporator, and then purified by column chromatography with dichloromethane/n-hexane (1:4) as the extraction solvent, obtaining Organic metal compound (V). The synthesis pathway of the above reaction was as follows:

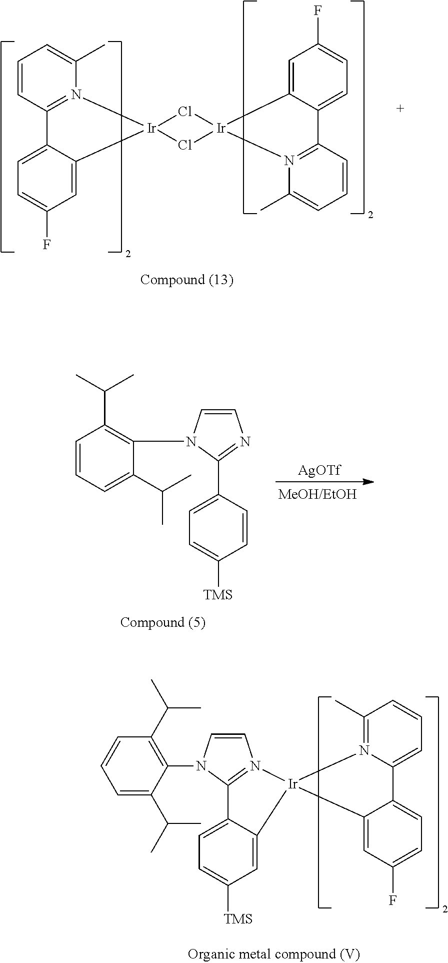

Preparation of Organic Metal Compound (XII)

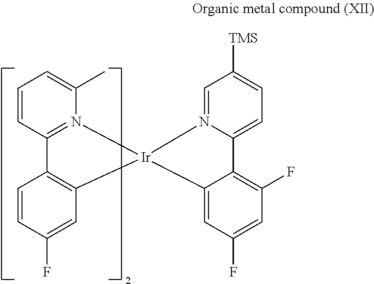

Compound (13) (1.2 g, 1 mmole), Compound (11)(0.66 g, 2.5 mmole), silver trifluoromethanesulfonate (AgOTf) (0.56 g, 2.2 mmole), methanol (MeOH) (5 mL), and ethanol (EtOH) (5 mL) were added into a reaction bottle. Next, the mixture was stirred at 90° C. for 12 hr. Next, the reaction bottle was cooled to room temperature. Next, the result was extracted three times using dichloromethane (CH₂Cl₂) and water as the extraction solvent. Next, an organic phase was separated, dried, filtrated and concentrated by rotary evaporator, and then purified by column chromatography with dichloromethane/n-hexane (1:3) as the extraction solvent, obtaining Organic metal compound (XII). The synthesis pathway of the above reaction was as follows:

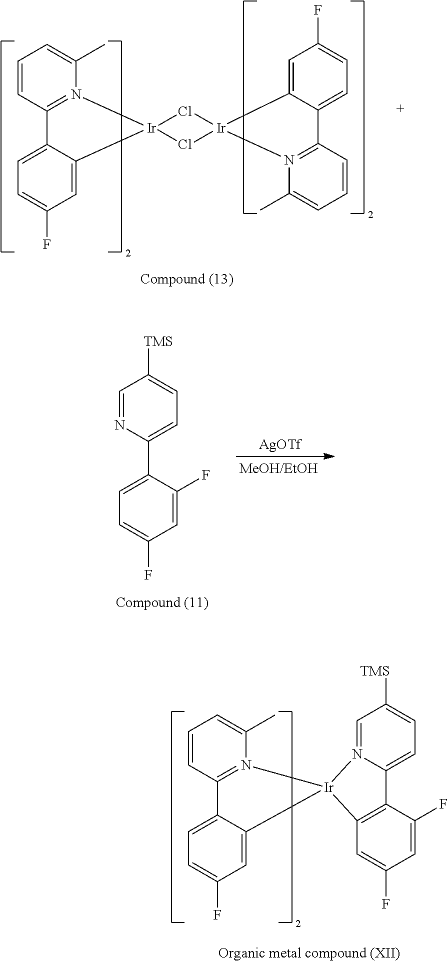

Next, the measurement results of nuclear magnetic resonance spectrometry of Organic metal compound (I)-(XII) disclosed in Examples 1-12 are shown in Table 2.

| | nuclear magnetic resonance spectrum data |
|---|---|
| Organic metal | ¹H NMR (500 MHz, CD₃OD, 294 K): 7.40 (d, 6H), 6.87 (s, 3H), 6.79~6.73 |
| compound (I) | (m, 6H), 6.50 (t, 3H), 6.38 (t, 3H), 6.15 (d, 3H), 2.08 (s, 9H), 1.89 (s, 9H), |
| | 0.32 (s, 27H) |
| Organic metal | ¹H NMR (500 MHz, d-DMSO, 294 K): 7.56 (t, 3H), 7.40~7.35 (m, 9H), |
| compound (II) | 7.01 (s, 3H), 6.70 (s, 3H), 6.42 (d, 3H), 5.93 (d, 3H), 2.54~2.51 (m, 3H), |
| | 2.25~2.22 (m, 3H), 1.17 (d, 9H), 0.93 (d, 9H), 0.90 (d, 9H), 0.82 (d, 9H), |
| | 0.30 (s, 27H) |
| Organic metal | ¹H NMR (500 MHz, d-DMSO, 294 K): 7.46 (d, 6H), 7.23 (s, 3H), 6.65 (s, |
| compound (III) | 3H), 6.24~6.21 (m, 6H), 6.09~6.06 (m, 3H), 2.05 (s, 9H), 1.79 (s, 9H), 0.30 |
| | (s, 27H) |
| Organic metal | ¹H NMR (500 MHz, CDCl₃, 294 K): 7.74 (d, 1H), 7.71~7.65 (m, 2H), |
| compound (IV) | 7.56~7.50 (m, 2H), 7.44 (t, 1H), 7.31 (s, 1H), 7.27 (s, 1H), 6.82 (d, 1H), 6.76 |
| | (d, 1H), 6.61~6.46 (m, 6H), 6.39~6.36 (m, 2H), 6.12 (d, 1H), 6.01 (dd, 1H), |
| | 2.19 (s, 3H), 2.09 (s, 3H), 1.97 (s, 3H), 1.62 (s, 3H), 0.30 (s, 9H) |
| Organic metal | ¹H NMR (500 MHz, CDCl₃, 294 K): 7.82 (d, 2H), 7.77 (t, 1H), 7.69~7.62 |
| compound (V) | (m, 2H), 7.57 (t, 1H), 7.52 (t, 1H), 7.40~7.26 (m, 2H), 6.94 (d, 1H), 6.84 (d, |
| | 1H), 6.71~6.63 (m, 5H), 6.50 (d, 1H), 6.43 (s, 1H), 6.15~6.11 (m, 2H), |
| | 2.77~2.73 (m, 1H), 2.29 (s, 3H), 2.08 (s, 3H), 2.03~2.00 (m, 1H), 1.26 (d, |
| | 3H), 1.16 (d, 3H), 1.01 (d, 3H), 0.87 (d, 3H), 0.09 (s, 9H) |
| Organic metal | ¹H NMR (500 MHz, CDCl₃, 294 K): 8.362 (s, 1H), 8.24 (d, 1H), 7.72 (d, |
| compound (VI) | 1H), 7.54~7.49 (m, 2H), 7.36~7.26 (m, 4H), 7.74 (d, 2H), 6.59(s, 1H), |
| | 6.44~6.36 (m, 4H), 6.22~6.09 (m, 4H), 6.01 (dd, 1H), 2.78 (m, 1H), 2.56 (m, |
| | 1H), 2.34 (m, 1H), 1.88 (m, 1H), 1.22 (d, 3H), 1.18 (d, 3H), 1.07 (d, 3H), |
| | 0.99 (d, 3H), 0.96 (d, 3H), 0.91 (d, 3H), 0.86 (d, 3H), 0.77 (d, 3H), 0.22 (s, |
| | 9H) |
| Organic metal | ¹H NMR (500 MHz, CDCl₃, 294 K): 8.30 (d, 1H), 8.13 (s, 1H), 7.76 (d, 1H), |
| compound (VII) | 7.44 (t, 2H), 7.25~7.21 (m, 4H), 6.68 (d, 2H), 6.58 (s, 1H), 6.52 (d, 1H), |
| | 6.44~6.39 (m, 2H), 6.25 (s, 1H), 6.14~6.05 (m, 3H), 2.71 (m, 1H), 2.57 (m, |
| | 1H), 2.43 (m, 1H), 2.18 (m, 1H), 1.22 (d, 3H), 1.17 (d, 3H), 1.06~0.95 (m, |
| | 18H), 0.09 (s, 9H) |
| Organic metal | ¹H NMR (500 MHz, CDCl₃, 294 K): 8.30 (d, 2H), 8.26 (s, 1H), 7.80 (d, 1H), |
| compound (VIII) | 7.54~7.50 (m, 2H), 7.34~7.31 (m, 4H), 6.69 (d, 2H), 6.55~6.48 (m, 3H), |
| | 6.27~6.13 (m, 5H), 6.03 (dd, 1H), 2.68 (m, 1H), 2.59 (m, 1H), 2.43 (m, 1H), |
| | 2.20 (m, 1H), 1.21~1.17 (m, 9H), 1.05 (d, 3H), 1.00 (d, 3H), 0.97~0.92 (m, |
| | 6H), 0.89 (d, 3H), 0.09 (s, 9H) |
| Organic metal | ¹H NMR (500 MHz, CDCl₃, 294 K): 8.31 (d, 1H), 8.14 (s, 1H), 7.84 (d, 1H), |
| compound (IX) | 7.45 (t, 2H), 7.25~7.22 (m, 4H), 6.71 (d, 2H), 6.56 (s, 1H), 6.53 (t, 1H), 6.35 |
| | (d, 1H), 6.22 (s, 1H), 6.17~6.05 (m, 3H), 2.67 (m, 1H), 2.53 (m, 1H), 2.43 |
| | (m, 1H), 2.17 (m, 1H), 1.21 (d, 3H), 1.18 (d, 3H), 1.06 (d, 3H), 1.03~0.98 |
| | (m, 12H), 0.95 (d, 3H), 0.11 (s, 9H) |
| Organic metal | ¹H NMR (500 MHz, CDCl₃, 294 K): 7.93 (d, 1H), 7.88 (d, 1H), 7.81 (d, |
| compound (X) | 1H), 7.70 (t, 2H), 7.60~7.57 (m, 2H), 7.52 (t, 1H), 7.31 (d, 2H), 6.92\grave{ }6.88 |
| | (m, 3H), 6.82 (t, 1H), 6.75~6.72 (m, 3H), 6.65 (t, 1H), 6.60~6.57 (m, 3H), |
| | 6.42~6.40 (m, 2H), 6.20 (d, 1H), 2.09 (s, 3H), 1.51 (s, 3H), 0.32 (s, 9H) |
| Organic metal | ¹H NMR (500 MHz, CDCl₃, 294 K): 8.07 (d, 1H), 7.85 (d, 1H), 7.80 (d, |
| compound (XI) | 1H), 7.73 (d, 1H), 7.65 (s, 1H), 7.58~7.54 (m, 3H), 7.48 (t, 1H), 6.94~6.89 |
| | (m, 2H), 6.85 (t, 1H), 6.77~6.70 (m, 3H), 6.56 (d, 1H), 6.43 (d, 1H), |
| | 6.35~6.30 (m, 1H), 6.10 (dd, 1H), 1.96 (s, 3H), 1.86 (s, 3H), 0.02 (s, 9H) |
| Organic metal | ¹H NMR (500 MHz, CDCl₃, 294 K): 8.10 (d, 1H), 7.75~7.7.68 (m, 3H), |
| compound (XII) | 7.62~7.54 (m, 4H), 7.49 (t, 1H), 6.90 (d, 1H), 6.74 (d, 1H), 6.63 (t, 1H), 6.54 |
| | (t, 1H), 6.36 (t, 1H), 6.21 (d, 1H), 6.06 (t, 2H), 1.93 (s, 3H), 1.85 (s, 3H), |
| | 0.02 (s, 9H) |

Next, Organic metal compounds (I)-(XII) of Examples 1-12 were individually dissolved into dichloromethane, obtaining solutions with a concentration of 10⁻⁵M. Next, the photoluminescence (PL) spectra of the solutions were measured, and the results are shown in Table 3. In addition, Compound (14) (having a structure represented by

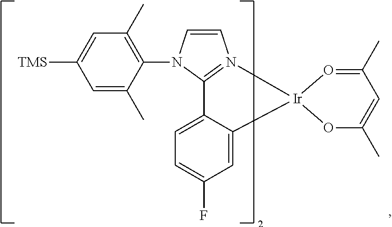

and TMS is (CH₃)₃Si—) was dissolved into dichloromethane, obtaining solutions with a concentration of 10⁻⁵M. Next, the photoluminescence (PL) spectrum of the solution was measured, and the results are shown in Table 3.

TABLE 3

| | maximum luminous intensity |
|---|---|
| | peak (Emission λmax) |
| Organic metal compound (I) | 476 nm |
| Organic metal compound (II) | 490 nm |
| Organic metal compound (III) | 484 nm |
| compound (14) | 540 nm |
| Organic metal compound (IV) | 497 nm |
| Organic metal compound (V) | 499 nm |
| Organic metal compound (VI) | 509 nm |
| Organic metal compound (VII) | 497 nm |
| Organic metal compound (VIII) | 500 nm |
| Organic metal compound (IX) | 487 nm |
| Organic metal compound (X) | 522 nm |
| Organic metal compound (XI) | 508 nm |
| Organic metal compound (XII) | 493 nm |

As shown in Table 3, the organic metal compounds of the disclosure having a structure represented by Formula (I) have a maximum luminous intensity peak between 476 nm and 522 nm (i.e. the organic metal compounds of the disclosure are greenish blue phosphorescent materials). It should be noted that, when the organic metal compound of the disclosure has three 1,2-diphenyl-1H-imidazole-derived ligand (wherein the ligand has a trimethyl silyl group), the organic metal compound exhibits a blue-shifted maximum luminous intensity peak. In addition, when replacing the acetyl acetone ligand of Compound (14) with 1,2-diphenyl-1H-imidazole-derived ligand (wherein the ligand has a trimethyl silyl group) of the disclosure, the obtained compound (i.e. Organic metal compound (III)) exhibits a blue-shifted maximum luminous intensity peak (having a 56 nm blue-shift in comparison with the maximum luminous intensity peak of Compound (14)).

Next, the HOMO (highest occupied molecular orbital) energy gap of Organic metal compound (III)-(XII) of Examples 3-12, Compound (15) (having a structure of

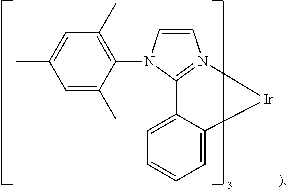

Compound (16) (having a structure of

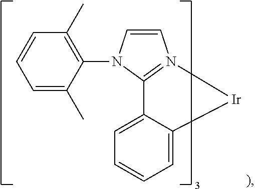

and Compound (17) (having a structure of

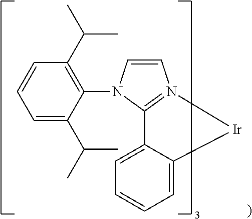

were measured, and the results are shown in Table 4:

TABLE 4

| | HOMO (highest occupied |
|---|---|
| | molecular orbital) energy gap |
| Compound (15) | 4.90 eV |
| Compound (16) | 4.92 eV |
| Compound (17) | 4.91 eV |
| Organic metal compound (III) | 5.17 eV |
| Organic metal compound (IV) | 5.15 eV |
| Organic metal compound (V) | 5.20 eV |
| Organic metal compound (VI) | 5.49 eV |
| Organic metal compound (VII) | 5.53 eV |
| Organic metal compound (VIII) | 5.37 eV |
| Organic metal compound (IX) | 5.49 eV |
| Organic metal compound (X) | 5.52 eV |
| Organic metal compound (XI) | 5.19 eV |
| Organic metal compound (XII) | 5.52 eV |

As shown in Table 4, the HOMO (highest occupied molecular orbital) energy gaps of Compound (15), Compound (16) and Compound (17) are about 4.9 eV. The conventional transport materials having a high operating lifespan, however, are not suitable for matching with the HOMO (highest occupied molecular orbital) energy gap of about 4.9 eV. In comparison with Compound (15), Compound (16) and Compound (17), the HOMO (highest occupied molecular orbital) energy gaps of the organic metal compounds of the disclosure are enhanced to more than 5.15 eV (the HOMO (highest occupied molecular orbital) energy gaps of Organic metal compound (X) and Organic metal compound (XII) are about 5.52 eV), since the trialkylsilyl group is introduced to the organic metal compounds. As a result, the HOMO (highest occupied molecular orbital) energy gaps of the organic metal compounds (as dopant) of the disclosure match the energy gap (5.5 eV) of the conventional transport materials having a high operating lifespan. Therefore, the electrons and holes are apt to migrate from the host material to the dopant material.

Organic Light-Emitting Device

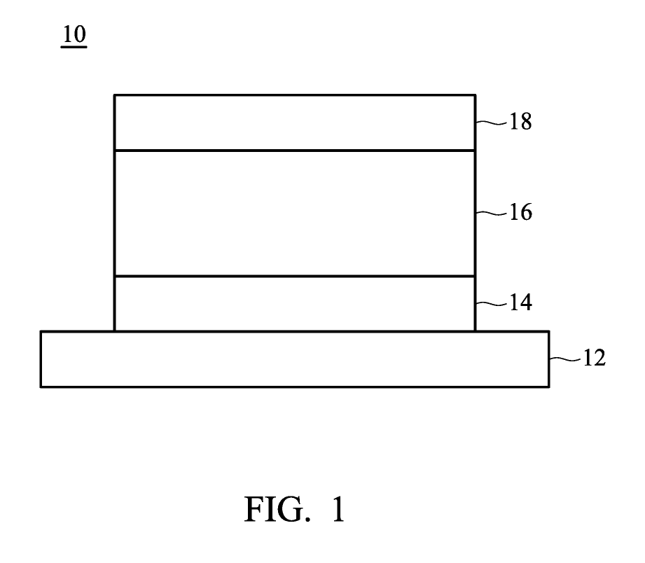

FIG. 1 shows an embodiment of an organic light-emitting device 10. The organic light-emitting device 10 includes a substrate 12, a bottom electrode 14, an organic light-emitting element 16, and a top electrode 18, as shown in FIG. 2. The organic light-emitting device can be a top-emission, bottom-emission, or dual-emission device. The substrate 12 can be a glass, plastic, or semiconductor substrate. Suitable materials for the bottom and top electrodes can be Ca, Ag, Mg, Al, Li, In, Au, Ni, W, Pt, Cu, indium tin oxide (ITO), indium zinc oxide (IZO), aluminum zinc oxide (AZO), or zinc oxide (ZnO), formed by sputtering, electron beam evaporation, thermal evaporation, or chemical vapor deposition. Furthermore, at least one of the bottom and top electrodes 14 and 18 is transparent.

The organic light-emitting element 16 at least includes an emission layer, and can further include a hole injection layer, a hole transport layer, an electron transport layer, and an electron injection layer. In an embodiment of the disclosure, at least one layer of the organic light-emitting element 16 includes the aforementioned organic metal compound.

According to another embodiment of the disclosure, the organic light-emitting device can be a phosphorescent organic light-emitting device, and the emission layer of the organic light-emitting element 16 can include a host material and a phosphorescence dopant, wherein the phosphorescence dopant can include the aforementioned organic metal compound having the structure represented by Formula (I). The emission layer emits blue or cyan light under a bias voltage. The dose of the dopant is not limited and can optionally be modified by a person of ordinary skill in the art.

In order to clearly disclose the organic light-emitting devices of the disclosure, the following examples (having an emitting layer employing the organic metal compounds of the disclosure) are intended to illustrate the disclosure more fully without limiting their scope, since numerous modifications and variations will be apparent to those skilled in this art.

### Example 13

A glass substrate with an indium tin oxide (ITO) film with a thickness of 150 nm was provided and then washed with a cleaning agent, acetone, and isopropanol with ultrasonic agitation. After drying with nitrogen flow, the ITO film was subjected to a UV/ozone treatment for 30 min. Next, PEDOT (poly(3,4)-ethylendioxythiophen):PSS (e-polystyrenesulfonate) was coated on the ITO film by a blade and spin coating process (with a rotation rate of 500 rpm for 5 sec and a rotation rate of 2000 rpm for 30 sec and) and baked at 130° C. for 10 min to form a PEDO:PSS film serving as a hole injection layer (with a thickness of 40 nm). Next, TAPC (1,1-bis[4-[N, N′-di (p-tolyl)amino]phenyl]cyclobexane, with a thickness of 35 nm), TCTA (4, 4′, 4′-tri (N-carbazolyl)triphenylamine) doped with Organic metal compound (I) (the weight ratio between TCTA and Organic metal compound (I) was 100:6, with a thickness of 10 nm), TmPyPB (1,3,5-tri[(3-pyridyl)-phen-3-yl]benzene, with a thickness of 42 nm), LiF (with a thickness of 0.5 nm), and Al (with a thickness of 120 nm) were subsequently formed on the PEDO:PSS film at 10⁻⁶ torr, obtaining Organic light-emitting device (I) after encapsulation. The materials and layers of Organic light-emitting device (I) are described in the following: ITO/PEDOT:PSS/TAPC/TCTA:Organic metal compound (I)(6%)/TmPyPB/LiF/Al.

Next, the optical properties (such as maximum luminous intensity peak (Emission λmax) of electroluminescent (EL) spectrum, voltage, brightness, current efficiency (cd/A), power efficiency (lm/W) and C.I.E coordinates (x, y)) of Organic light-emitting device (I) were measured with a spectra colorimeter and a luminance meter. The results are shown in Table 5.

### Example 14

Example 14 was performed in the same manner as in Example 13 except that Organic metal compound (II) was substituted for Organic metal compound (I), obtaining Organic light-emitting device (II). The materials and layers of Organic light-emitting device (II) are described in the following: ITO/PEDOT:PSS/TAPC/TCTA:Organic metal compound (II)(6%)/TmPyPB/LiF/Al.

Next, the optical properties (such as maximum luminous intensity peak (Emission λmax) of electroluminescent (EL) spectrum, voltage, brightness, current efficiency (cd/A), power efficiency (lm/W) and C.I.E coordinates (x, y)) of Organic light-emitting device (II) were measured with a spectra colorimeter and a luminance meter. The results are shown in Table 5.

### Example 15

Example 15 was performed in the same manner as in Example 13 except that Organic metal compound (IV) was substituted for Organic metal compound (I), obtaining Organic light-emitting device (III). The materials and layers of Organic light-emitting device (III) are described in the following: ITO/PEDOT:PSS/TAPC/TCTA:Organic metal compound (IV)(6%)/TmPyPB/LiF/Al.

Next, the optical properties (such as maximum luminous intensity peak (Emission λmax) of electroluminescent (EL) spectrum, voltage, brightness, current efficiency (cd/A), power efficiency (lm/W) and C.I.E coordinates (x, y)) of Organic light-emitting device (III) were measured with a spectra colorimeter and a luminance meter. The results are shown in Table 5.

### Example 16

Example 16 was performed in the same manner as in Example 13 except that Organic metal compound (VII) was substituted for Organic metal compound (I), obtaining Organic light-emitting device (IV). The materials and layers of Organic light-emitting device (IV) are described in the following: ITO/PEDOT:PSS/TAPC/TCTA:Organic metal compound (VII)(6%)/TmPyPB/LiF/Al.

Next, the optical properties (such as maximum luminous intensity peak (Emission λmax) of electroluminescent (EL) spectrum, voltage, brightness, current efficiency (cd/A), power efficiency (lm/W) and C.I.E coordinates (x, y)) of Organic light-emitting device (IV) were measured with a spectra colorimeter and a luminance meter. The results are shown in Table 5.

### Example 17

Example 17 was performed in the same manner as in Example 13 except that Organic metal compound (XII) was substituted for Organic metal compound (I), obtaining Organic light-emitting device (V). The materials and layers of Organic light-emitting device (V) are described in the following: ITO/PEDOT:PSS/TAPC/TCTA:Organic metal compound (XII)(6%)/TmPyPB/LiF/Al.

Next, the optical properties (such as maximum luminous intensity peak (Emission λmax) of electroluminescent (EL) spectrum, voltage, brightness, current efficiency (cd/A), power efficiency (lm/W) and C.I.E coordinates (x, y)) of Organic light-emitting device (V) were measured with a spectra colorimeter and a luminance meter. The results are shown in Table 5.

### Comparative Example 1

Comparative Example 1 was performed in the same manner as in Example 13 except that Compound (15) (having a structure of

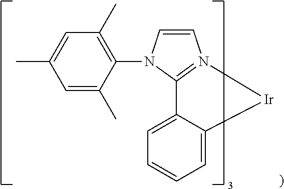

was substituted for Organic metal compound (I), obtaining Organic light-emitting device (VI). The materials and layers of Organic light-emitting device (VI) are described in the following: ITO/PEDOT:PSS/TAPC/TCTA: Compound (15) (6%)/TmPyPB/LiF/Al.

Next, the optical properties (such as maximum luminous intensity peak (Emission λmax) of electroluminescent (EL) spectrum, voltage, brightness, current efficiency (cd/A), power efficiency (lm/W) and C.I.E coordinates (x, y)) of Organic light-emitting device (VI) were measured with a spectra colorimeter and a luminance meter. The results are shown in Table 5.

TABLE 5

| | | | current | power | | Emission |
|---|---|---|---|---|---|---|
| | voltage | brightness | efficiency | efficiency | C.I.E | λmax |
| | (V) | (cd/m²) | (cd/A) | (lm/W) | coordinates | (nm) |
| Example 13 | 4.3 | 1,000 | 65.3 | 50.1 | (0.19, 0.52) | 476 |
| Example 14 | 4.3 | 1,000 | 68.1 | 50.4 | (0.22, 0.50) | 488 |
| Example 15 | 4.3 | 1,074 | 65.3 | 47.8 | (0.20, 0.54) | 497 |
| Example 16 | 4.3 | 1,059 | 78.9 | 64.5 | (0.21, 0.46) | 496 |
| Example 17 | 4.6 | 1,052 | 44.6 | 30.7 | (0.21, 0.51) | 492 |
| Comparative | 4.3 | 1,000 | 38.2 | 30.7 | (0.19, 0.40) | 476 |
| Example 1 | | | | | | |

As shown in Table 5, since the trialkylsilyl group is introduced into the organic metal compound, the HOMO (highest occupied molecular orbital) energy gap of the organic metal compound matches the conventional transport material. In comparison with the organic light-emitting device of Comparative Example 1, the organic light-emitting device employing the organic metal compound of the disclosure exhibits higher luminescent efficiency.

It will be clear that various modifications and variations can be made to the disclosed methods and materials. It is intended that the specification and examples be considered as exemplary only, with the true scope of the disclosure being indicated by the following claims and their equivalents.

What is claimed is:

1. An organic metal compound, having a structure of Formula (I): 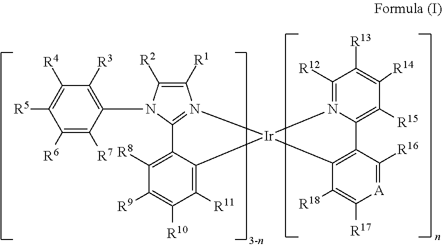
wherein R¹ and R² are independently hydrogen, halogen, C₁₋₈ alkyl group, C₁₋₈ haloalkyl group, C₁₋₈ alkoxy group, C₅₋₁₀ cycloalkyl group, or C₆₋₁₂ aryl group; R³, R⁴, R⁵, R⁶, R⁷, R⁸, R⁹, R¹⁰, R¹¹, R¹², R¹³, R¹⁴ and R¹⁵ are independently hydrogen, halogen, C₁₋₈ alkyl group, C₁₋₈ haloalkyl group, C₁₋₈ alkoxy group, C₅₋₁₀ cycloalkyl group, C₆₋₁₂ aryl group, or —Si(R¹⁹)₃, wherein R¹⁹ is independently C₁₋₈ alkyl group; R¹⁶, R¹⁷ and R¹⁸ are independently hydrogen, halogen, C₁₋₈ alkyl group, C₁₋₈ haloalkyl group, C₁₋₈ alkoxy group, C₅₋₁₀ cycloalkyl group, or C₆₋₁₂ aryl group; and, A is independently N, or CR²⁰, wherein R²⁰ is independently hydrogen, halogen, or C₁₋₈ alkyl group; and n meets the following conditions (1), (2) and (3):
(1) n is 0, and at least one of R³, R⁴, R⁵, R⁶, R⁷, R⁸, R⁹, R¹⁰ and R¹¹ is Si(R¹⁹)₃, wherein R¹⁹ is independently C₁₋₈ alkyl group;
(2) n is 1 or 2, and at least one of R³, R⁴, R⁵, R⁶, R⁷, R⁸, R⁹, R¹⁰ and R¹¹ is —Si(R¹⁹)₃, wherein R¹⁹ is independently C₁₋₈ alkyl group; and
(3) n is 3, and at least one of R¹², R¹³, R¹⁴ and R¹⁵ is —Si(R¹⁹)₃, wherein R¹⁹ is independently C₁₋₈ alkyl group.

2. The organic metal compound as claimed in claim 1, wherein R¹ and R² are independently hydrogen, fluorine, methyl group, ethyl group, propyl group, isopropyl group, butyl group, sec-butyl group, iso-butyl group, tert-butyl group, pentyl group, hexyl group, fluoromethyl, fluoroethyl, methoxy group, ethoxy group, propoxy group, isopropoxy group, butoxy group, sec-butoxy group, iso-butoxy group, tert-butoxy group, pentyloxy group, hexyloxy group, cyclopentyl group, cyclohexyl group, phenyl group, biphenyl group, or naphthyl group.

3. The organic metal compound as claimed in claim 1, wherein R³, R⁴, R⁵, R⁶, R⁷, R⁸, R⁹, R¹⁰, R¹¹, R¹², R¹³, R¹⁴ and R¹⁵ are independently hydrogen, fluorine, methyl group, ethyl group, propyl group, isopropyl group, butyl group, sec-butyl group, iso-butyl group, tert-butyl group, pentyl group, hexyl group, fluoromethyl, fluoroethyl, methoxy group, ethoxy group, propoxy group, isopropoxy group, butoxy group, sec-butoxy group, iso-butoxy group, tert-butoxy group, pentyloxy group, hexyloxy group, cyclopentyl group, cyclohexyl group, phenyl group, biphenyl group, naphthyl group, or trialkylsilyl group.

4. The organic metal compound as claimed in claim 1, wherein R¹⁶, R¹⁷ and R¹⁸ are independently hydrogen, fluorine, methyl group, ethyl group, propyl group, isopropyl group, butyl group, sec-butyl group, iso-butyl group, tert-butyl group, pentyl group, hexyl group, fluoromethyl, fluoroethyl, methoxy group, ethoxy group, propoxy group, isopropoxy group, butoxy group, sec-butoxy group, iso-butoxy group, tert-butoxy group, pentyloxy group, hexyloxy group, cyclopentyl group, cyclohexyl group, phenyl group, biphenyl group, or naphthyl group.

5. The organic metal compound as claimed in claim 1, wherein R²⁰ is independently hydrogen, fluorine, methyl group, ethyl group, propyl group, isopropyl group, butyl group, sec-butyl group, iso-butyl group, tert-butyl group, pentyl group, or hexyl group.

6. The organic metal compound as claimed in claim 1, wherein the organic metal compound is 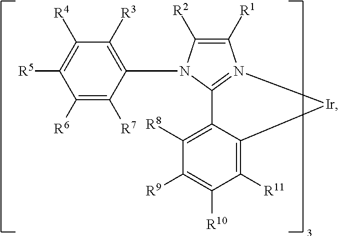
wherein R¹ and R² are independently hydrogen, halogen, C₁₋₈ alkyl group, C₁₋₈ haloalkyl group, C₁₋₈ alkoxy group, C₅₋₁₀ cycloalkyl group, or C₆₋₁₂ aryl group; and, R³, R⁴, R⁵, R⁶, R⁷, R⁸, R⁹, R¹⁰ and R¹¹ are independently hydrogen, halogen, C₁₋₈ alkyl group, C₁₋₈ haloalkyl group, C₁₋₈ alkoxy group, C₅₋₁₀ cycloalkyl group, C₆₋₁₂ aryl group, or —Si(R¹⁹)₃, wherein R¹⁹ is independently C₁₋₈ alkyl group; and at least one of R³, R⁴, R⁵, R⁶, R, R⁸, R⁹, R¹⁰, and R¹¹ is —Si(R¹⁹)₃.

7. The organic metal compound as claimed in claim 1, wherein the organic metal compound is 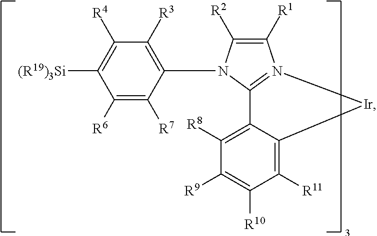
wherein R¹, R², R³, R⁴, R⁶ and R⁷ are independently hydrogen, halogen, C₁₋₈ alkyl group, C₁₋₈ haloalkyl group, C₁₋₈ alkoxy group, C₅₋₁₀ cycloalkyl group, or C₆₋₁₂ aryl group; R⁸, R⁹, R¹⁰ and R¹¹ are independently hydrogen, halogen, C₁₋₈ alkyl group, C₁₋₈ haloalkyl group, C₁₋₈ alkoxy group, C₅₋₁₀ cycloalkyl group, C₆₋₁₂ aryl group, or —Si(R¹⁹)₃; and, R¹⁹ is independently C₁₋₈ alkyl group.

8. The organic metal compound as claimed in claim 1, wherein the organic metal compound is 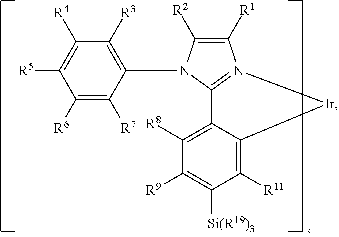
wherein R¹, R², R⁸, R⁹ and R¹¹ are independently hydrogen, halogen, C₁₋₈ alkyl group, C₁₋₈ haloalkyl group, C₁₋₈ alkoxy group, C₅₋₁₀ cycloalkyl group, or C₆₋₁₂ aryl group; R³, R⁴, R⁵, R⁶ and R⁷ are independently hydrogen, halogen, C₁₋₈ alkyl group, C₁₋₈ haloalkyl group, C₁₋₈ alkoxy group, C₅₋₁₀ cycloalkyl group, C₆₋₁₂ aryl group, or —Si(R¹⁹)₃; and, R¹⁹ is independently C₁₋₈ alkyl group.

9. The organic metal compound as claimed in claim 1, wherein the organic metal compound is 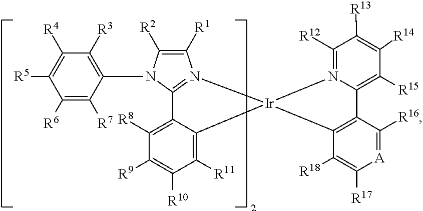
wherein R¹ and R² are independently hydrogen, halogen, C₁₋₈ alkyl group, C₁₋₈ haloalkyl group, C₁₋₈ alkoxy group, C₅₋₁₀ cycloalkyl group, or C₆₋₁₂ aryl group; R³, R⁴, R⁵, R⁶, R⁷, R⁸, R⁹, R¹⁰, R¹¹, R¹², R¹³, R¹⁴ and R¹⁵ are independently hydrogen, halogen, C₁₋₈ alkyl group, C₁₋₈ haloalkyl group, C₁₋₈ alkoxy group, C₅₋₁₀ cycloalkyl group, C₆₋₁₂ aryl group, or —Si(R¹⁹)₃, wherein R¹⁹ is independently C₁₋₈ alkyl group; R¹⁶, R¹⁷ and R¹⁸ are independently hydrogen, halogen, C₁₋₈ alkyl group, C₁₋₈ haloalkyl group, C₁₋₈ alkoxy group, C₅₋₁₀ cycloalkyl group, or C₆₋₁₂ aryl group; and, A is N, or CR²⁰, wherein R²⁰ is hydrogen, halogen, or C₁₋₈ alkyl group; and at least one of R³, R⁴, R⁵, R⁶, R⁷, R⁸, R⁹, R¹⁰, R¹¹, R¹², R¹³, R¹⁴ and R¹⁵ is —Si(R¹⁹)₃.

10. The organic metal compound as claimed in claim 1, wherein the organic metal compound is 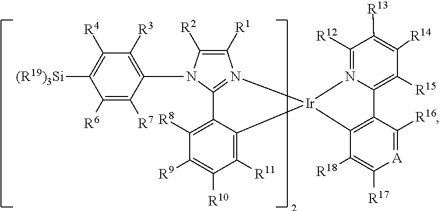
wherein R¹, R², R³, R⁴, R⁶, R⁷, R¹⁶, R¹⁷ and R¹⁸ are independently hydrogen, halogen, C₁₋₈ alkyl group, C₁₋₈ haloalkyl group, C₁₋₈ alkoxy group, C₅₋₁₀ cycloalkyl group, or C₆₋₁₂ aryl group; R⁸, R⁹, R¹⁰, R¹¹, R¹², R¹³, R¹⁴ and R¹⁵ are independently hydrogen, halogen, C₁₋₈ alkyl group, C₁₋₈ haloalkyl group, C₁₋₈ alkoxy group, C₅₋₁₀ cycloalkyl group, C₆₋₁₂ aryl group, or —Si(R¹⁹)₃; R¹⁹ is independently C₁₋₈ alkyl group; and, A is N, or CR²⁰, wherein R²⁰ is hydrogen, halogen, or C₁₋₈ alkyl group.

11. The organic metal compound as claimed in claim 1, wherein the organic metal compound is 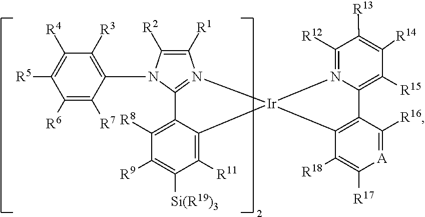
wherein R¹, R², R⁸, R⁹, R¹¹, R¹⁶, R¹⁷ and R¹⁸ are independently hydrogen, halogen, C₁₋₈ alkyl group, C₁₋₈ haloalkyl group, C₁₋₈ alkoxy group, C₅₋₁₀ cycloalkyl group, or C₆₋₁₂ aryl group; R³, R⁴, R⁵, R⁶, R, R¹², R¹³, R¹⁴ and R¹⁵ are independently hydrogen, halogen, C₁₋₈ alkyl group, C₁₋₈ haloalkyl group, C₁₋₈ alkoxy group, C₅₋₁₀ cycloalkyl group, C₆₋₁₂ aryl group, or —Si(R¹⁹)₃; R¹⁹ is independently C₁₋₈ alkyl group; and, A is N, or CR²⁰, wherein R²⁰ is hydrogen, halogen, or C₁₋₈ alkyl group.

12. The organic metal compound as claimed in claim 1, wherein the organic metal compound is 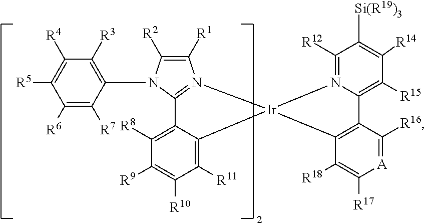
wherein R¹, R², R¹², R¹⁴, R¹⁵, R¹⁶, R¹⁷ and R¹⁸ are independently hydrogen, halogen, C₁₋₈ alkyl group, C₁₋₈ haloalkyl group, C₁₋₈ alkoxy group, C₅₋₁₀ cycloalkyl group, or C₆₋₁₂ aryl group; R³, R⁴, R⁵, R⁶, R⁷, R⁸, R⁹, R¹⁰ and R¹¹ are independently hydrogen, halogen, C₁₋₈ alkyl group, C₁₋₈ haloalkyl group, C₁₋₈ alkoxy group, C₅₋₁₀ cycloalkyl group, C₆₋₁₂ aryl group, or —Si(R¹⁹)₃; R¹⁹ is independently C₁₋₈ alkyl group; and, A is N, or CR²⁰, wherein R²⁰ is hydrogen, halogen, or C₁₋₈ alkyl group.

13. The organic metal compound as claimed in claim 1, wherein the organic metal compound is 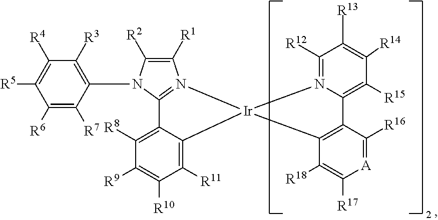
wherein R¹ and R² are independently hydrogen, halogen, C₁₋₈ alkyl group, C₁₋₈ haloalkyl group, C₁₋₈ alkoxy group, C₅₋₁₀ cycloalkyl group, or C₆₋₁₂ aryl group; R³, R⁴, R⁵, R⁶, R⁷, R⁸, R⁹, R¹⁰, R¹¹, R¹², R¹³, R¹⁴ and R¹⁵ are independently hydrogen, halogen, C₁₋₈ alkyl group, C₁₋₈ haloalkyl group, C₁₋₈ alkoxy group, C₅₋₁₀ cycloalkyl group, C₆₋₁₂ aryl group, or —Si(R¹⁹)₃, wherein R¹⁹ is independently C₁₋₈ alkyl group; R¹⁶, R¹⁷ and R¹⁸ are independently hydrogen, halogen, C₁₋₈ alkyl group, C₁₋₈ haloalkyl group, C₁₋₈ alkoxy group, C₅₋₁₀ cycloalkyl group, or C₆₋₁₂ aryl group; and, A is independently N, or CR²⁰, wherein R²⁰ is independently hydrogen, halogen, or C₁₋₈ alkyl group; and at least one of R³, R⁴, R⁵, R⁶, R⁷, R⁸, R⁹, R¹⁰, R¹¹, R¹², R¹³, R¹⁴ and R¹⁵ is —Si(R¹⁹)₃.

14. The organic metal compound as claimed in claim 1, wherein the organic metal compound is 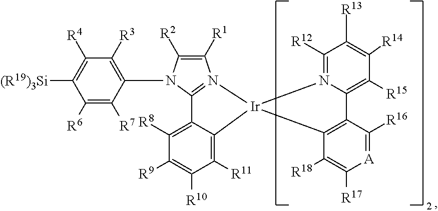
wherein R¹, R², R³, R⁴, R⁶, R⁷, R¹⁶, R¹⁷ and R¹⁸ are independently hydrogen, halogen, C₁₋₈ alkyl group, C₁₋₈ haloalkyl group, C₁₋₈ alkoxy group, C₅₋₁₀ cycloalkyl group, or C₆₋₁₂ aryl group; R⁸, R⁹, R¹⁰, R¹¹, R¹², R, R¹⁴ and R¹⁵ are independently hydrogen, halogen, C₁₋₈ alkyl group, C₁₋₈ haloalkyl group, C₁₋₈ alkoxy group, C₅₋₁₀ cycloalkyl group, C₆₋₁₂ aryl group, or —Si(R¹⁹)₃; R¹⁹ is independently C₁₋₈ alkyl group; and, A is independently N, or CR²⁰, wherein R²⁰ is independently hydrogen, halogen, or C₁₋₈ alkyl group.

15. The organic metal compound as claimed in claim 1, wherein the organic metal compound is 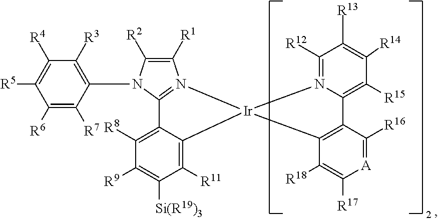
wherein R¹, R², R⁸, R⁹, R¹¹, R¹⁶, R¹⁷ and R¹⁸ are independently hydrogen, halogen, C₁₋₈ alkyl group, C₁₋₈ haloalkyl group, C₁₋₈ alkoxy group, C₅₋₁₀ cycloalkyl group, or C₆₋₁₂ aryl group; R³, R⁴, R⁵, R⁶, R⁷, R¹², R, R¹⁴ and R¹⁵ are independently hydrogen, halogen, C₁₋₈ alkyl group, C₁₋₈ haloalkyl group, C₁₋₈ alkoxy group, C₅₋₁₀ cycloalkyl group, C₆₋₁₂ aryl group, or —Si(R¹⁹)₃; R¹⁹ is independently C₁₋₈ alkyl group; and, A is independently N, or CR²⁰, wherein R²⁰ is independently hydrogen, halogen, or C₁₋₈ alkyl group.

16. The organic metal compound as claimed in claim 1, wherein the organic metal compound is 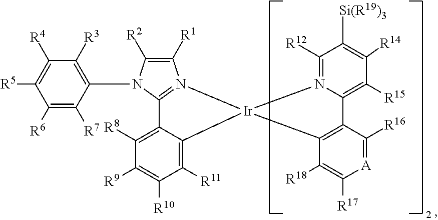
wherein R¹, R², R¹², R¹⁴, R¹⁵, R¹⁶, R¹⁷ and R¹⁸ are independently hydrogen, halogen, C₁₋₈ alkyl group, C₁₋₈ haloalkyl group, C₁₋₈ alkoxy group, C₅₋₁₀ cycloalkyl group, or C₆₋₁₂ aryl group; R³, R⁴, R⁵, R⁶, R⁷, R⁸, R⁹, R¹⁰ and R¹¹ are independently hydrogen, halogen, C₁₋₈ alkyl group, C₁₋₈ haloalkyl group, C₁₋₈ alkoxy group, C₅₋₁₀ cycloalkyl group, C₆₋₁₂ aryl group, or —Si(R¹⁹)₃; R¹⁹ is independently C₁₋₈ alkyl group; and, A is independently N, or CR²⁰, wherein R²⁰ is independently hydrogen, halogen, or C₁₋₈ alkyl group.

17. The organic metal compound as claimed in claim 1, wherein the organic metal compound is 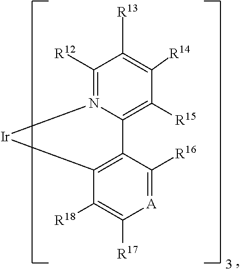
wherein R¹⁶, R¹⁷ and R¹⁸ are independently hydrogen, halogen, C₁₋₈ alkyl group, C₁₋₈ haloalkyl group, C₁₋₈ alkoxy group, C₅₋₁₀ cycloalkyl group, or C₆₋₁₂ aryl group; R¹², R¹³, R¹⁴ and R¹⁵ are independently hydrogen, halogen, C₁₋₈ alkyl group, C₁₋₈ haloalkyl group, C₁₋₈ alkoxy group, C₅₋₁₀ cycloalkyl group, C₆₋₁₂ aryl group, or —Si(R¹⁹)₃, and at least one of R¹², R¹³, R¹⁴, and R¹⁵ is —Si(R¹⁹)₃; R¹⁹ is independently C₁₋₈ alkyl group; and, A is independently N, or CR²⁰, wherein R²⁰ is independently hydrogen, halogen, or C₁₋₈ alkyl group.

18. The organic metal compound as claimed in claim 1, wherein the organic metal compound is 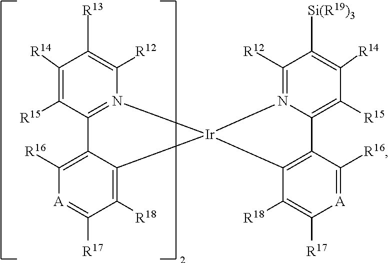
wherein R¹², R¹³, R¹⁴, R¹⁵, R¹⁶, R¹⁷ and R¹⁸ are independently hydrogen, halogen, C₁₋₈ alkyl group, C₁₋₈ haloalkyl group, C₁₋₈ alkoxy group, C₅₋₁₀ cycloalkyl group, or C₆₋₁₂ aryl group; R¹⁹ is independently C₁₋₈ alkyl group; and, A is independently N, or CR²⁰, wherein R²⁰ is independently hydrogen, halogen, or C₁₋₈ alkyl group.

19. The organic metal compound as claimed in claim 1, wherein the organic metal compound is 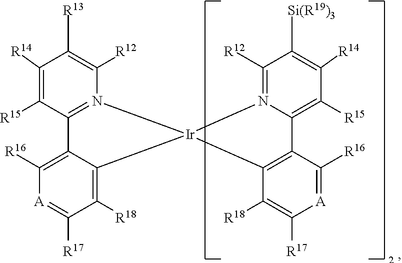
wherein R¹², R¹³, R¹⁴, R¹⁵, R¹⁶, R¹⁷ and R¹⁸ are independently hydrogen, halogen, C₁₋₈ alkyl group, C₁₋₈ haloalkyl group, C₁₋₈ alkoxy group, C₅₋₁₀ cycloalkyl group, or C₆₋₁₂ aryl group; R¹⁹ is independently C₁₋₈ alkyl group; and, A is independently N, or CR²⁰, wherein R²⁰ is independently hydrogen, halogen, or C₁₋₈ alkyl group.

20. An organic light-emitting device, comprising:
a pair of electrodes; and
an organic light-emitting element, disposed between the electrodes, wherein the organic light-emitting element comprises the organic metal compound as claimed in claim 1.
